(19) United States
(12) Patent Application Publication
(10) Pub. No.: US 2022/0208671 A1
(43) Pub. Date: Jun. 30, 2022

(54) SEMICONDUCTOR-MOUNTED PRODUCT

(71) Applicant: Panasonic Intellectual Property Management Co., Ltd., Osaka (JP)

(72) Inventors: Atsushi YAMAGUCHI, Osaka (JP); Yasuo FUKUHARA, Osaka (JP)

(21) Appl. No.: 17/697,184

(22) Filed: Mar. 17, 2022

Related U.S. Application Data
(63) Continuation of application No. 16/476,071, filed on Jul. 3, 2019.

(51) Int. Cl. H01L 23/498; H01L 23/00

(52) U.S. Cl. CPC H01L 23/49838; H01L 24/17; H01L 24/81; H01L 2924/014; H01L 2224/13113; H01L 2224/13139; H01L 2224/13147; H01L 2224/13111

(57) ABSTRACT

A semiconductor-mounted product includes a semiconductor package, a wiring substrate, four or more soldered portions, and a resin-reinforced portion. Each of the soldered portions electrically connects the semiconductor package to the wiring of the wiring substrate. The resin-reinforced portion is formed on a side surface of each of the soldered portions. Each of the soldered portions has a first solder region formed closer to the semiconductor package than the wiring substrate and a second solder region formed closer to the wiring substrate than the semiconductor package. A proportion of a void present in a polygon connecting centers of soldered portions located at outermost positions among the soldered portions to a sum of the void and the resin-reinforced portion is from 10% to 99%, inclusive.

### FIELD OF THE INVENTION

The present technical field relates to a semiconductor-mounted product obtained using a semiconductor part.

### DESCRIPTION OF THE RELATED ART

As a method of mounting a semiconductor part on a substrate, there is a method in which a bump formed on the lower surface of the semiconductor part using solder as a component is soldered to an electrode of a wiring substrate for conduction. However, the holding ability for holding the semiconductor part on the wiring substrate is often insufficient only by the solder joint between the bump and the electrode. In this case, a thermosetting resin such as an epoxy resin is used to reinforce the bond between the semiconductor part and the substrate.

As a reinforcement method using a resin, methods such as solder fill and side fill have been proposed (for example, International Publication No. WO 2012/042809). In addition, a technique using a resin-reinforced solder paste composed of a thermosetting resin composition containing a solder powder and a flux component has been proposed (for example, Unexamined Japanese Patent Publication No. JP 2011-176050). In addition, a technique has been proposed in which a resin composition which does not contain solder is attached to the surface of a solder ball (for example, Unexamined Japanese Patent Publication No. JP 2012-84845).

An example of conventional reinforcement using a resin is described with reference to FIG. 29A to FIG. 29C. FIG. 29A to FIG. 29C are cross-sectional views illustrating an example of surface mounting using a conventional resin-reinforced solder paste.

As illustrated in FIG. 29A, thermosetting resin composition 1 is printed in advance on electrode 3 formed on the surface of circuit board 2. Thereafter, sealing material 5 is applied to the surface of thermosetting resin composition 1 or circuit board 2 using syringe 4.

Next, semiconductor device 6 is mounted on circuit board 2 coated with sealing material 5 as illustrated in FIG. 29B. In other words, terminal 7 formed on one surface of semiconductor device 6 is directed to circuit board 2, and semiconductor device 6 is landed on circuit board 3 as indicated by an arrow.

Subsequently, circuit board 2 and semiconductor device 6 are heated and joint portion 10 is formed by soldered portion 8 and resin-cured portion 9 as illustrated in FIG. 29C. FIG. 29C corresponds to a cross-sectional view of semiconductor device 6 after mounting.

### SUMMARY OF THE INVENTION

A semiconductor-mounted product of the present invention includes a semiconductor package, a wiring substrate, four or more soldered portions, and a resin-reinforced portion. The wiring substrate has a mounting surface on which the wiring is disposed, and the semiconductor package is mounted on this mounting surface. Each of the soldered portions electrically connects the semiconductor package to the wiring. The resin-reinforced portion is disposed on a side surface of each of the soldered portions. Each of the soldered portions has a first solder region located closer to the semiconductor package than the wiring substrate and a second solder region located closer to the wiring substrate than the semiconductor package. A proportion of a void present in a polygon connecting centers of the soldered portions located at outermost positions among the soldered portions to a sum of the void and the resin-reinforced portion is from 10% to 99%, inclusive. The proportion of the void is evaluated in a surface which is apart from the mounting surface by ¼ of a distance between the semiconductor package and the wiring substrate and is parallel to the mounting surface. Alternatively, the proportion of the void is evaluated in a surface which is apart from the mounting surface by ⅓ of a distance from a position most distant from the wiring of the resin-reinforced portion to the mounting surface and is parallel to the mounting surface.

This configuration improves the reparability of the semiconductor-mounted product.

### BRIEF DESCRIPTION OF DRAWINGS

FIG. 1A is a cross-sectional view of a semiconductor part according to a first exemplary embodiment of the present invention.

FIG. 1B is a perspective view of the semiconductor part illustrated in FIG. 1A.

FIG. 2A is an enlarged cross-sectional view of a main section (near a bump) of the semiconductor part illustrated in FIG. 1A.

FIG. 2B is an enlarged cross-sectional view of a main section (near the bump) of another configuration of the semiconductor part illustrated in FIG. 1A.

FIG. 3A is an explanatory view illustrating a manufacturing procedure of the semiconductor part according to the first exemplary embodiment of the present invention.

FIG. 3B is an explanatory view illustrating a manufacturing procedure of the semiconductor part continued from FIG. 3A.

FIG. 4A is a partial cross-sectional view of a semiconductor-mounted product to which the semiconductor part according to the first exemplary embodiment of the present invention is applied.

FIG. 4B is a perspective view of the semiconductor-mounted product illustrated in FIG. 4A.

FIG. 5 is an explanatory view illustrating a procedure for mounting the semiconductor part illustrated in FIG. 1A on the surface of a wiring substrate.

FIG. 6 is an enlarged view of a main section in the procedure illustrated in FIG. 5.

FIG. 7 is an enlarged cross-sectional view of a main section illustrating a state in which the semiconductor part is mounted on the surface of the wiring substrate by the procedure illustrated in FIG. 5 or FIG. 6 and reflow is not yet performed.

FIG. 8 is an enlarged cross-sectional view of a main section of the semiconductor-mounted product illustrated in FIG. 4A.

FIG. 9 is a plan view schematically illustrating a mounting surface of the semiconductor-mounted product according to the first exemplary embodiment of the present invention.

FIG. 10 is a cross-sectional view for explaining a mounting example of a semiconductor part illustrated as one comparative example.

FIG. 11 is a cross-sectional view illustrating a state before reflow in the mounting example according to the comparative example illustrated in FIG. 10.

FIG. 12 is a cross-sectional view for explaining a mounting state after reflow in the mounting example according to the comparative example illustrated in FIG. 10.

FIG. 13 is a cross-sectional view of a main section of a semiconductor part according to a second exemplary embodiment of the present invention.

FIG. 14 is an explanatory view of a method of manufacturing the semiconductor part illustrated in FIG. 13.

FIG. 15A is a cross-sectional view of a main section for explaining a manufacturing procedure of the semiconductor part illustrated in FIG. 13.

FIG. 15B is a cross-sectional view of a main section for explaining the manufacturing procedure of the semiconductor part illustrated in FIG. 13.

FIG. 16A is a cross-sectional view of a main section of another semiconductor part according to the second exemplary embodiment of the present invention.

FIG. 16B is a cross-sectional view of a main section of still another semiconductor part according to the second exemplary embodiment of the present invention.

FIG. 17 is a cross-sectional view of a main section of a semiconductor part according to a third exemplary embodiment of the present invention.

FIG. 18 is an enlarged cross-sectional view for schematically explaining a solder joint structure of a semiconductor-mounted product according to the third exemplary embodiment of the present invention.

FIG. 19A is a cross-sectional view of a main section for explaining a manufacturing procedure of the semiconductor part according to the third exemplary embodiment of the present invention.

FIG. 19B is a cross-sectional view of a main section for explaining a procedure next to the procedure illustrated in FIG. 19A.

FIG. 19C is a cross-sectional view of a main section for explaining a procedure next to the procedure illustrated in FIG. 19B.

FIG. 20A is a plan view illustrating the shapes of and positional relationship between a bump and a first thermosetting resin binder when the bump is coated with the first thermosetting resin binder in a fourth exemplary embodiment of the present invention.

FIG. 20B is a plan view illustrating the shapes of and positional relationship between the bump and the first thermosetting resin binder when the bump is coated with the first thermosetting resin binder in the fourth exemplary embodiment of the present invention.

FIG. 21 is an enlarged cross-sectional view for schematically explaining a solder joint structure of a semiconductor-mounted product according to the fourth exemplary embodiment of the present invention.

FIG. 22A is a view illustrating heights of left and right resin-reinforced portions in various examples in which a soldered portion is fabricated by the first thermosetting resin binder illustrated in FIG. 20A.

FIG. 22B is a view illustrating heights of left and right resin-reinforced portions in various examples in which a soldered portion is fabricated by further shifting the center from the center of a bump than the first thermosetting resin binder illustrated in FIG. 20A.

FIG. 23A is a longitudinal sectional view of a semiconductor-mounted product according to a fifth exemplary embodiment of the present invention.

FIG. 23B is a transverse sectional view taken along line 23B-23B in FIG. 23A.

FIG. 24A is a longitudinal sectional view of another semiconductor-mounted product according to the fifth exemplary embodiment of the present invention.

FIG. 24B is a transverse sectional view taken along line 24B-24B in FIG. 24A.

FIG. 24C is a transverse sectional view illustrating an example of a configuration on line 24C-24C in FIG. 24A.

FIG. 24D is a transverse sectional view illustrating another example of the configuration on line 24D-24D in FIG. 24A.

FIG. 25A is a cross-sectional view illustrating an example of a configuration of a space provided in a resin-reinforced portion and four soldered portions surrounding the space.

FIG. 25B is a cross-sectional view illustrating another example of the configuration of the space provided in the resin-reinforced portion and four soldered portions surrounding the space.

FIG. 25C is a cross-sectional view illustrating still another example of the configuration of the space provided in the resin-reinforced portion and four soldered portions surrounding the space.

FIG. 26 is a first schematic cross-sectional view illustrating a height position at which a void ratio is evaluated.

FIG. 27 is a second schematic cross-sectional view illustrating a height position at which the void ratio is evaluated.

FIG. 28A is a schematic cross-sectional view of a semiconductor-mounted product for explaining the void ratio.

FIG. 28B is a schematic cross-sectional view of the semiconductor-mounted product for explaining a disposition of a soldered portion.

FIG. 29A is a cross-sectional view for explaining a procedure of surface mounting using a conventional resin-reinforced solder paste.

FIG. 29B is a cross-sectional view illustrating a procedure continued from FIG. 29A.

FIG. 29C is a cross-sectional view illustrating a procedure continued from FIG. 29B.

### DETAILED DESCRIPTION OF THE PREFERRED EMBODIMENTS

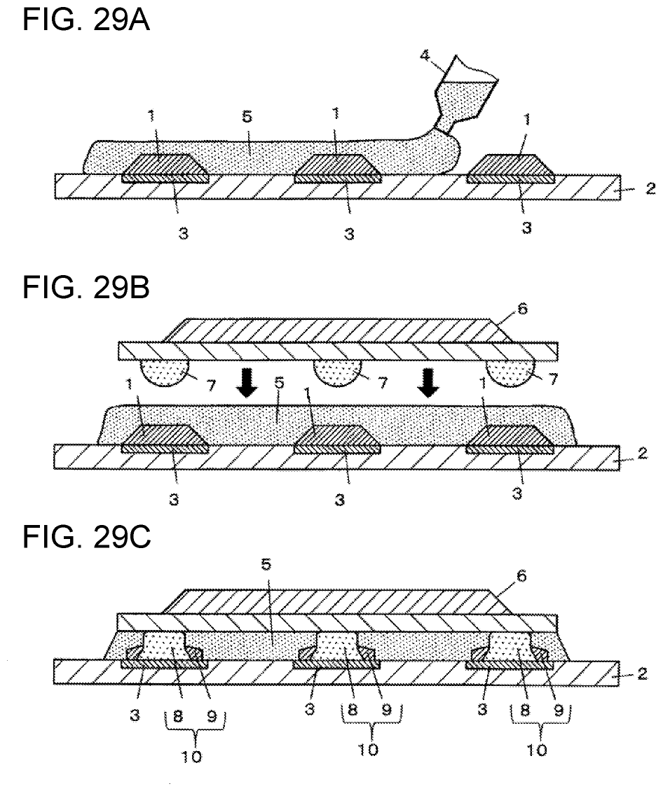

Prior to the description of the present exemplary embodiment, problems in a conventional semiconductor device illustrated in FIG. 29A to FIG. 29C are described. In the conventional semiconductor device, sealing material 5 and thermosetting resin composition 1 may be attached to the surface of terminal 7 as illustrated in FIG. 29B. In this manner, sealing material 5 and thermosetting resin composition 1 attached to the surface of terminal 7 may inhibit the electrical connection between soldered portion 8 and electrode 3 when junction 10 is formed as illustrated in FIG. 29C.

Moreover, thermosetting resin composition 1 is pushed and spread downward when convex terminal 7 is pressed onto thermosetting resin composition 1 which has been printed and formed in advance. For this reason, the height of resin-cured portion 9 for reinforcing the periphery of soldered portion 8 may not be sufficient and resin-cured portion 9 may not be able to reinforce the periphery of soldered portion 8.

Hereinafter, exemplary embodiments of the present invention are described with reference to the drawings. In the respective exemplary embodiments, the same reference numeral is given to the same configuration as that in the preceding exemplary embodiment and the detailed description thereof may be omitted. Incidentally, the present invention is not limited to the following first to fourth exemplary embodiments. It is possible to change the exemplary embodiments within the scope of the concept of the present invention. It is also possible to apply the contents of the first to fourth exemplary embodiments in combination with one another.

### First Exemplary Embodiment

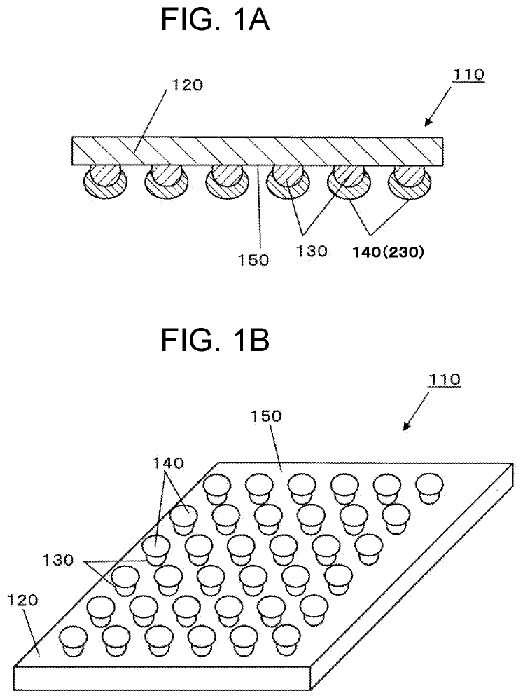

FIG. 1A is a cross-sectional view of semiconductor part 110 according to a first exemplary embodiment of the present invention. FIG. 1B is a perspective view of semiconductor part 110 illustrated in FIG. 1A.

Semiconductor part 110 includes semiconductor package 120 having mounting surface 150, bump 130, and covering portion 140. Bump 130 is formed on mounting surface 150. Covering portion 140 covers a tip portion of bump 130. Specifically, a plurality of bumps 130 are formed on mounting surface 150 of semiconductor package 120 at predetermined intervals. Covering portions 140 provided on the surfaces of the respective bumps 130 are apart from each other, and the electric insulation between adjacent bumps 130 is maintained.

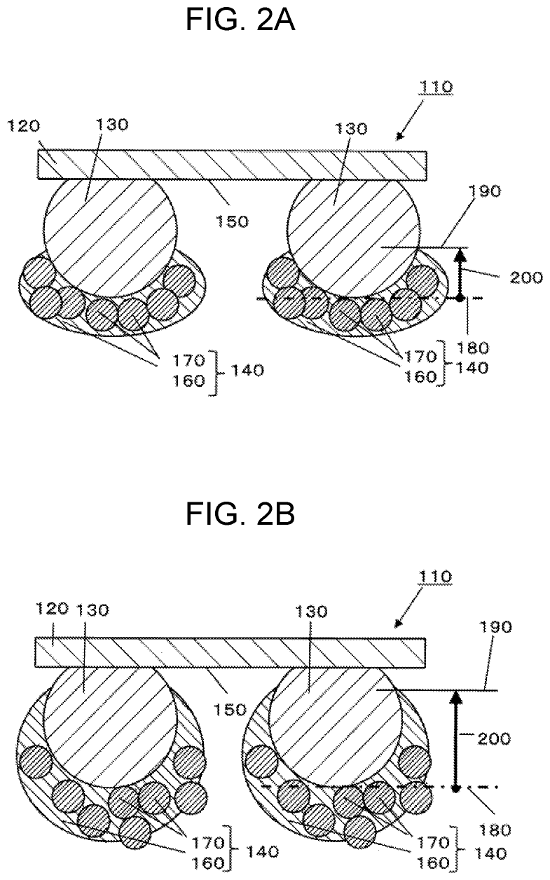

FIG. 2A and FIG. 2B are enlarged cross-sectional views of main sections (near bump 130) of semiconductor part 110. The difference between FIG. 2A and FIG. 2B is the size of covering portion 140.

Bump 130 is formed of first solder. On the other hand, covering portion 140 is formed of a first composition containing solder powder 170 composed of second solder, a flux component (not illustrated), and first thermosetting resin binder (hereinafter, first binder) 160.

First, semiconductor part 110 is described in more detail. Semiconductor package 120 is not particularly limited as long as it is in a form in which bump 130 composed of a solder ball and the like is formed on the mounting surface of semiconductor package 120. An example of semiconductor package 120 includes BGA (Ball Grid Array Package), CSP (Chip Scale Package) and the like in which a solder ball is provided as bump 130 on the lower surface of an interposer of an organic substrate, a semiconductor chip is mounted on the upper surface, and sealing is performed using a sealing resin.

Next, the first solder constituting bump 130 is described. The solder material constituting the first solder is not particularly limited. As the first solder, for example, a solder material containing Sn as a base can be used. As the first solder, a solder material having a melting point higher than that of solder powder 170 (second solder) contained in covering portion 140 is preferable. It is useful to use a Sn-Ag-Cu-based solder material (for example, a solder material called SAC 305) as the first solder. As a solder material having a high melting point is used as the first solder, bump 130 melts after solder powder 170 melts at the time of reflow. In order to melt bump 130 at a temperature close to the temperature at which solder powder 170 melts at the time of reflow, it is useful to use an alloy containing Bi as the first solder. As a solder alloy containing Bi is used as the first solder, the melting temperature of bump 130 can be lowered. As described above, the first solder forming bump 130 can be appropriately selected according to the application.

Next, each material of first composition 230 constructing covering portion 140 is described. The second solder constituting solder powder 170 is not particularly limited, but, for example, a solder alloy containing Sn as a base can be used. As the second solder, it is desirable to use, for example, a solder alloy containing Sn and Ag, Cu, Bi, Zn, In and the like. As the second solder, a solder material having a melting point lower than that of bump 130 (first solder) is particularly preferable. It is useful to use a solder material having a relatively low melting point as the second solder. When a solder material having a low melting point is used as the second solder, solder powder 170 melts before bump 130 melts at the time of reflow, and semiconductor package 120 and the wiring substrate are suitably soldered.

A specific example of the second solder having a low melting point includes, for example, a Sn-Bi-based solder material containing Bi as an essential component. For example, the eutectic point of Sn-Bi-based solder is 139° C. The melting point of the second solder can be set to be between 139° C. and 232° C. by selecting a solder material containing Bi as the second solder. In addition, as a solder material containing Bi is used as the second solder, the wettability to bump 130 and the wettability to the wiring on the wiring substrate are enhanced. In addition, as a solder material containing Bi is used as the second solder, the melting temperature of solder powder 170 is lowered and the melting behavior of solder powder 170 can be matched with the thermal curing behavior of first binder 160.

The content of solder powder 170 in the first composition is preferably in a range of from 40% by mass to 95% by mass, inclusive. When the content is in this range, it is possible to sufficiently exert the reinforcing effect by a resin-reinforced portion to be described later in addition to the electrical bonding property. Furthermore, it is more preferable that the content is in a range of from 70% by mass to 95% by mass, inclusive, since deterioration in coating workability due to an increase in viscosity of the first composition can be suppressed. Incidentally, solder powder 170 is present in the first composition in a dispersed state and the dispersed state of solder powder 170 is maintained in covering portion 140 as well.

The flux component is not particularly limited, and rosin component materials typified by abietic acid, various kinds of amines and salts thereof, sebacate salts, organic acids such as adipic acid and glutaric acid, and the like can be used. These flux components may be one kind of component or may be a mixture of two or more kinds of components.

The content of flux component is preferably set to be in a range of from 1% by mass to 50% by mass, inclusive, with respect to the total amount of the flux component and first binder 160. In this range, the flux component can exert excellent flux action, and the flux component further improves the mechanical bonding property and electrical bonding property by the cured product of covering portion 140.

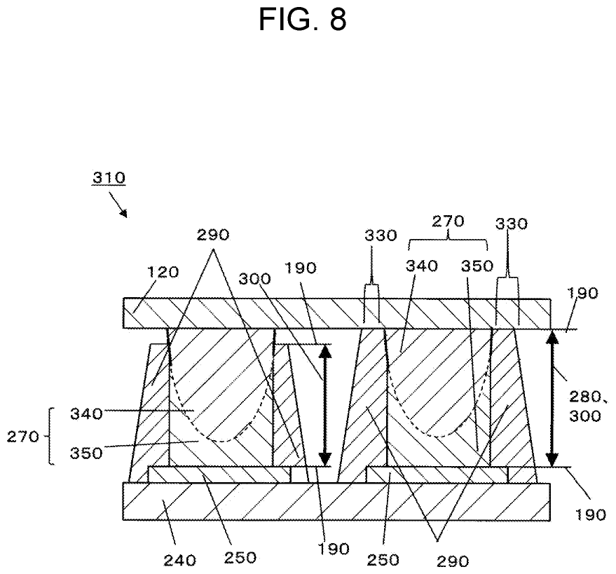

First binder 160 is present in covering portion 140 in an uncured state or a B-stage state. First binder 160 forms resin-reinforced portion 290 surrounding the side surface of soldered portion 270 at the time of reflow as illustrated in FIG. 8 to be described later. For this reason, first binder 160 is not particularly limited as long as it is a resin which can form resin-reinforced portion 290 surrounding the side surface of soldered portion 270 at the time of reflow. As first binder 160, a resin containing an epoxy resin and a curing agent as main components is preferable. Epoxy resins cure at relatively low temperatures and exhibit high adhesive property. As a resin containing an epoxy resin and a curing agent as main components is used as first binder 160, sufficient curability and a sufficient reinforcing effect required for part mounting are obtained even at a solder reflow temperature lower than the conventional solder reflow temperature.

As the epoxy resin, it is preferable to use an epoxy resin which is liquid at normal temperature. When such an epoxy resin is used, other components such as solder powder 170 can be easily dispersed in the epoxy resin. Incidentally, “being liquid at normal temperature” means to exhibit fluidity in a temperature range of from 5° C. to 28° C., inclusive, at atmospheric pressure, particularly around 18° C. of room temperature. As this epoxy resin which is liquid at normal temperature, the molecular weight and molecular structure are not particularly limited and various kinds of resins can be used as long as the resin has two or more epoxy groups in one molecule. Specifically, it is possible to use, for example, various kinds of liquid epoxy resins such as glycidyl ether type, glycidyl amine type, glycidyl ester type, and olefin oxidation type (alicyclic) liquid epoxy resins. More specifically, it is possible to use, for example, bisphenol type epoxy resins such as bisphenol A type epoxy resin and bisphenol F type epoxy resin, hydrogenated bisphenol type epoxy resins such as hydrogenated bisphenol A type epoxy resin and hydrogenated bisphenol F type epoxy resin, biphenyl type epoxy resin, naphthalene ring-containing epoxy resin, alicyclic epoxy resin, dicyclopentadiene type epoxy resin, phenol novolac type epoxy resin, cresol novolac type epoxy resin, triphenylmethane type epoxy resin, aliphatic epoxy resin, and triglycidyl isocyanurate. These may be used singly, or two or more kinds thereof may be used concurrently. Among these, bisphenol type epoxy resins and hydrogenated bisphenol type epoxy resins are preferable as the epoxy resin which is liquid at normal temperature when a decrease in viscosity of covering portion 140 and improvement in physical properties of the cured product are taken into consideration.

In addition, as the epoxy resin, an epoxy resin which is solid at normal temperature can be used concurrently with the epoxy resin which is liquid at normal temperature. As the epoxy resin which is solid at normal temperature, it is possible to use, for example, biphenyl type epoxy resin, dicyclopentadiene type epoxy resin, and an epoxy resin having a triazine skeleton.

As a curing agent for the epoxy resin, it is possible to use acid anhydrides, phenol novolacs, various kinds of thiol compounds, various kinds of amines, dicyandiamide, imidazoles, metal complexes, and adducts compounds thereof, for example, adduct modified products of polyamines. The amount of curing agent used is appropriately set, but for example, it is desirable to set the amount to be in a range of from 3 parts by mass to 20 parts by mass, inclusive, with respect to 100 parts by mass of the epoxy resin. In addition, it is more desirable to set the amount to be in a range of from 5 parts by mass to 15 parts by mass, inclusive. In addition, it is desirable that the ratio of stoichiometric equivalent of the curing agent to the epoxy equivalent of the epoxy resin is set to be in a range of from 0.8 to 1.2, inclusive.

In first binder 160, a curing accelerator can be blended, if necessary, in addition to the epoxy resin and the curing agent. As the curing accelerator, it is possible to use imidazoles, tertiary amines, cyclic amines such as 1,8-diazabicyclo(5.4.0)undecene-7 and 1,5-diazabicyclo(4.3.0)nonene-5 and tetraphenylborate salts thereof, trialkyl phosphines such as tributyl phosphine, triaryl phosphines such as triphenyl phosphine, quaternary phosphonium salts such as tetraphenylphosphonium tetraphenylborate and tetra(n-butyl)phosphonium tetraphenylborate; metal complexes such as Fe acetylacetonate, and adducts compounds thereof. The amount of these curing accelerators blended may be appropriately set in consideration of gelation time and storage stability.

First composition 230 may contain commonly used modifiers, additives and the like in addition to the components described above. In addition, a solvent having a low boiling point and a plasticizer may be added to first composition 230 for the purpose of adjusting the viscosity and the fluidity. In addition, hardened castor oil, stearic acid amide and the like may be added to first composition 230 as a thixotropy imparting agent for holding the printing shape.

The method of preparing first composition 230 is not particularly limited, and first composition 230 can be prepared, for example, by the following method. First, solder powder 170, a part or whole of the epoxy resin, and the flux component are mixed together to prepare a mixture. Thereafter, the curing agent is added to and mixed with the mixture. In addition, in a case in which a part of the epoxy resin is first used at the time of preparation of a mixture, the remainder of the epoxy resin and the curing agent are added to and mixed with the mixture.

Next, the covering state of the surface of bump 130 by covering portion 140 is described in more detail.

In FIG. 2A and FIG. 2B, dashed line 180 indicates the position of the tip portion of bump 130. Auxiliary line 190 indicates the position of the end portion of covering portion 140 which covers the surface of bump 130. Arrow 200 indicates the height of covering portion 140 which covers the surface of bump 130 from the tip portion of bump 130. As illustrated in FIG. 2A and FIG. 2B, covering portion 140 covers the surface of bump 130 from the tip portion of bump 130 to the side surface thereof. In other words, it is preferable that covering portion 140 continuously covers the tip portion of bump 130 and at least a part of the side surface of bump 130.

Moreover, it is preferable that covering portion 140 is 40% or more of the height of bump 130 when the height from the tip portion of bump 130 to mounting surface 150 of semiconductor package 120 is defined as the height of bump 130. In other words, it is preferable that the end portion of covering portion 140 on the side surface of bump 130 is closer to mounting surface 150 than a position to be 40% of the height of bump 130 from the tip portion of bump 130. Furthermore, it is more desirable that the height of covering portion 140 is 60% or more of the height of bump 130.

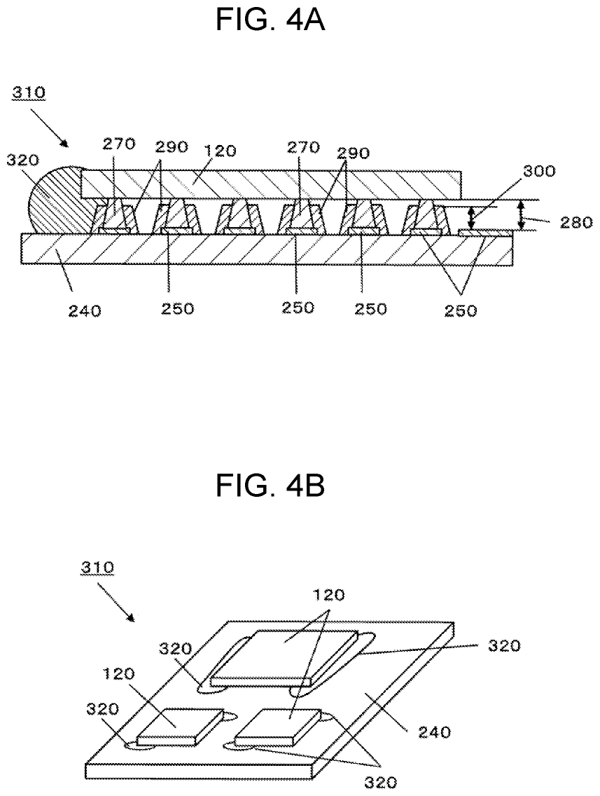

By setting the height of covering portion 140 to be 40% or more of the height of bumps 130, resin-reinforced portion 290 can be increased in height or thickness and the periphery of soldered portion 270 can be to reinforced in a wall shape in FIG. 4A and the like to be described later.

Incidentally, the fact that the height of covering portion 140 is 100% is a state in which the entire surface of bump 130 is covered with covering portion 140. In other words, this state is a state in which covering portion 140 continuously covers from the tip portion of bump 130 to mounting surface 150 of semiconductor package 120.

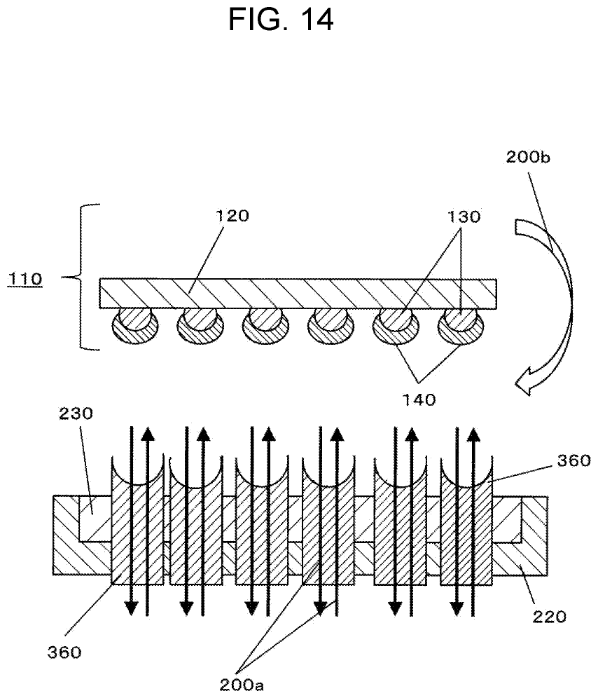

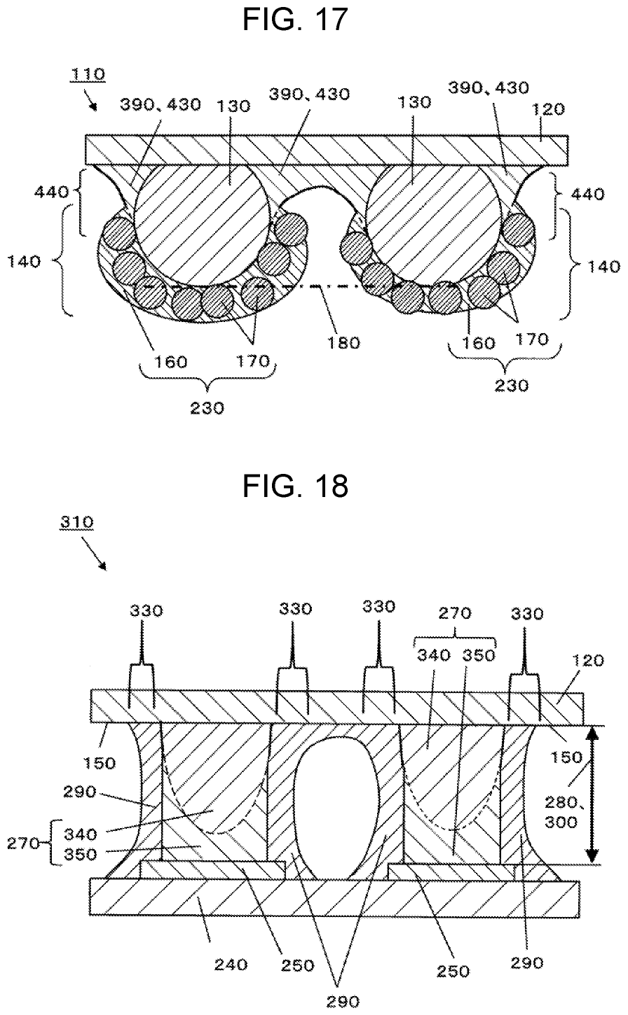

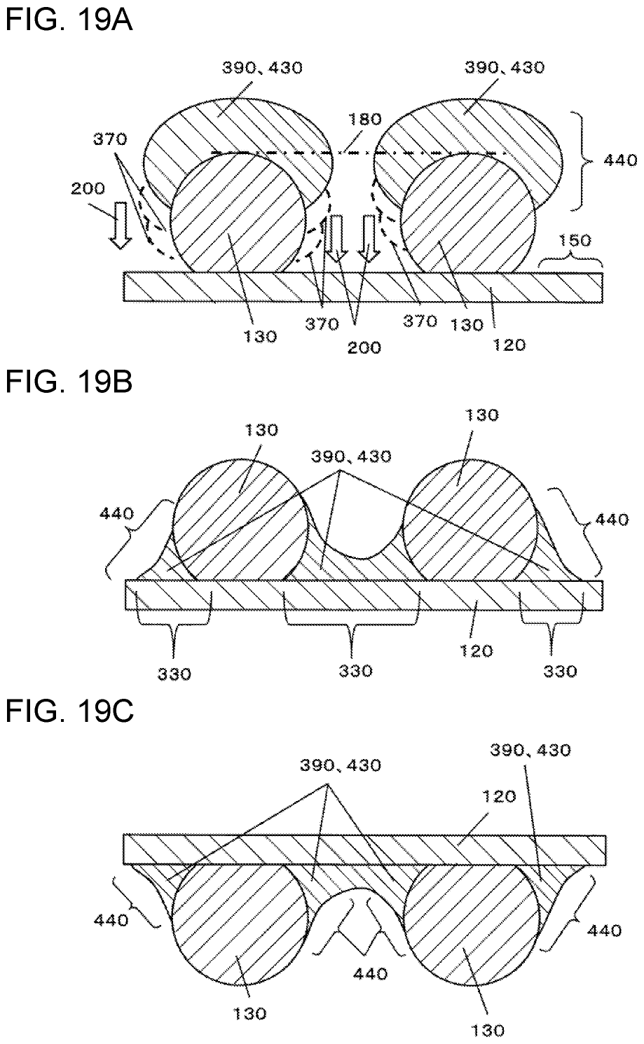

Incidentally, in a case in which the height of covering portion 140 is 100%, solder powder 170 contained in covering portion 140 may be in direct contact with the mounting surface of semiconductor package 120 between two adjacent bumps 130. In this case, it is useful to carry out the treatment which is illustrated in FIG. 14, FIG. 19A to FIG. 19C, and FIG. 17 and described in the second and third exemplary embodiments.

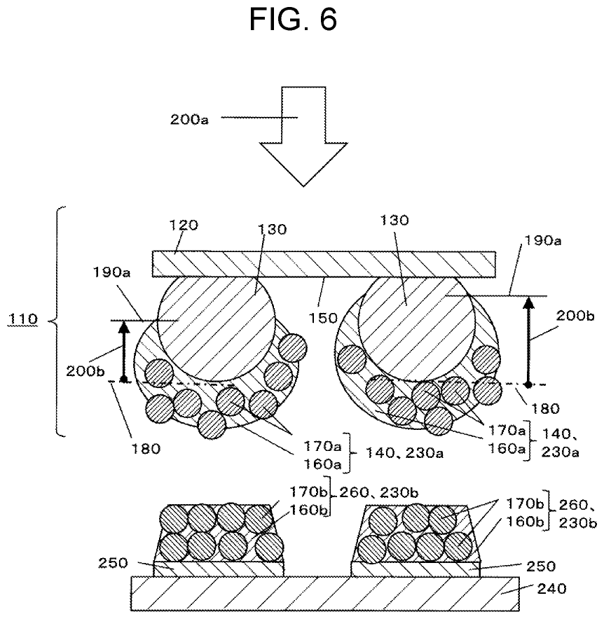

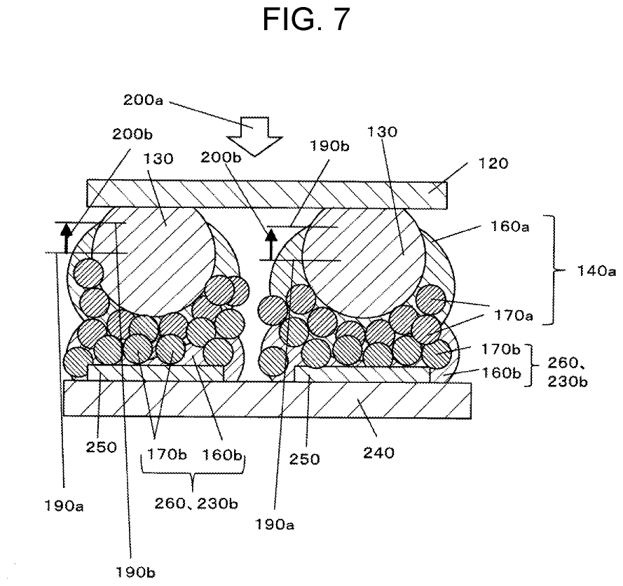

In addition, it is useful to carry out the steps illustrated in FIG. 6 and FIG. 7 to be described later even when the height of covering portion 140 is 40% of the height of bump 130 as illustrated in FIG. 2A. As the steps illustrated in FIG. 6 and FIG. 7 are carried out, the height of covering portion 140 before the reflow step is increased to 50% or more. Incidentally, FIG. 2B illustrates a state in which the height of covering portion 140 is increased to be higher than that in FIG. 2A. Incidentally, in order to increase the height of covering portion 140 to 50% or more and further to 60% or more of the height of bump 130, it is useful to shape the upper part of covering portion 140 by first binder 160 contained in covering portion 140 as illustrated in FIG. 2B.

It is desirable that the thickness of the region part covering the tip portion of bump 130 in covering portion 140 is 5 μm or more. Furthermore, it is desirable that the thickness is 10 μm or more and 20 μm or more to be thick. However, in this case, it is desirable that covering portions 140 formed on two adjacent bumps 130 do not come into contact with each other. Furthermore, it is desirable that the region part covering the tip portion of bump 130 in covering portion 140 is thicker than the region part covering the side surface of bump 130. In a case in which the thickness of covering portion 140 covering the bump tip portion of bump 130 is less than 5 μm, the formation of first solder region 340 and resin-reinforced portion 290 may be insufficient. In a case in which the region part covering the tip portion of bump 130 in covering portion 140 is the same as or thinner than the region part covering the side surface of bump 130, the mounting strength may be affected.

The average particle diameter of solder powder 170 contained in covering portion 140 is desirably from 3 μm to 30 μm, inclusive. When the average particle diameter is less than 3 μm, solder powder 170 may be expensive and the formation of second solder region 350 in FIG. 8 and the like to be described later may be insufficient. In a case in which the average particle diameter of solder powder 170 exceeds 30 μm, it may be difficult to uniformly form covering portion 140 on the surface of bump 130. Furthermore, variation and the like may be caused in the shape of second solder region 350 in FIG. 8 and the like to be described later.

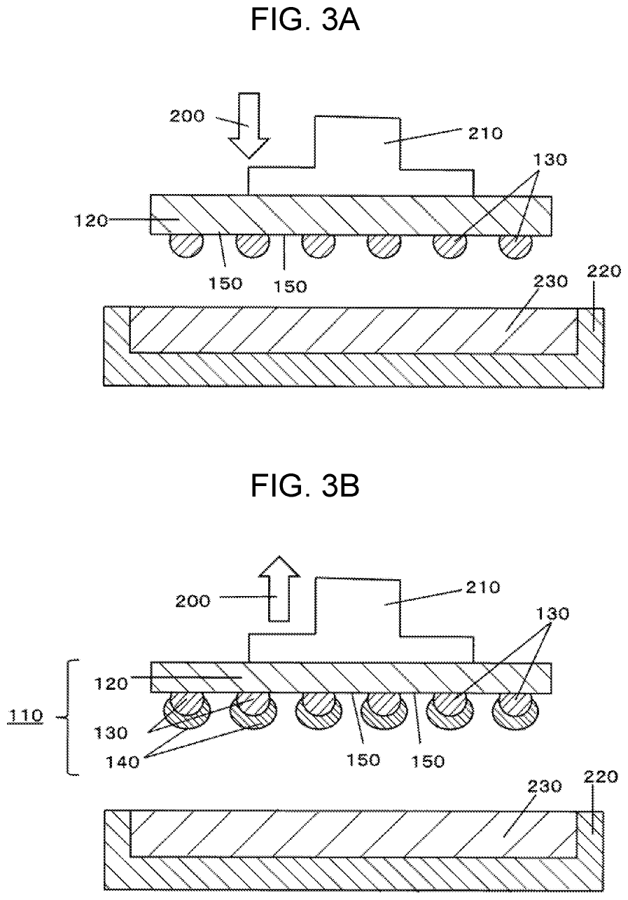

Next, an example of a method of manufacturing semiconductor part 110 is described with reference to FIG. 3A and FIG. 3B. FIG. 3A and FIG. 3B are explanatory views illustrating the manufacturing procedure of semiconductor part 110.

As illustrated in FIG. 3A, semiconductor package 120 on which bumps 130 are formed is held by part holding tool 210. A concave pool provided on transfer table 220 is filled with first composition 230.

In order to make the thickness (or depth) of first composition 230 poured into the pool of transfer table 220 constant, a rubber spatula, a stainless steel plate and the like are used. It is useful to flatten (at least 10 μm or less at 3 ρ/x, further 5 μm or less, 3 μm or less) the surface of first composition 230. The thickness (or depth) of first composition 230 on transfer table 220 may be lower than the height of bump 130.

In this state, bump 130 of semiconductor package 120 held by part holding tool 210 is moved in the direction indicated by arrow 200 and dipped in first composition 230.

Thereafter, bump 130 is pulled up from first composition 230 in the direction indicated by arrow 200 in FIG. 3B. In this manner, covering portion 140 formed of first composition 230 is continuously formed from the tip portion of bump 130 to the position to be 40% or more of the height of bump 130.

As described above, in order to manufacture semiconductor part 110, semiconductor package 120 having bumps 130 formed of the first solder on mounting surface 150 is prepared. Meanwhile, first composition 230 containing solder powder 170 composed of second solder, a flux component, and first binder 160 is prepared. Thereafter, the tip portion of bump 130 is covered with a part of first composition 230.

In addition, the procedures illustrated in FIG. 3A and FIG. 3B may be repeated plural times, if necessary. By this operation, while the height of covering portion 140 is kept constant, the thickness and attached amount (or supply amount, volume) of covering portion 140 are increased and the variation in the thickness and attached amount of covering portion 140 can be diminished.

Next, a semiconductor-mounted product having a solder joint structure according to the present first exemplary embodiment is described with reference to FIG. 4A and FIG. 4B by taking a case in which semiconductor part 110 is mounted on a wiring substrate as an example. FIG. 4A and FIG. 4B are a cross-sectional view and a perspective view of semiconductor-mounted product 310 configured by mounting semiconductor part 110 on wiring substrate 240, respectively.

As illustrated in FIG. 4A, semiconductor-mounted product 310 includes semiconductor package 120, wiring substrate 240, soldered portion 270, and resin-reinforced portion 290. Wiring 250 is formed on the surface of wiring substrate 240. Semiconductor package 120 is mounted on wiring substrate 240. Soldered portion 270 electrically connects semiconductor package 120 to wiring 250. Resin-reinforced portion 290 is formed on the side surface of soldered portion 270. Semiconductor-mounted product 310 has such a solder joint structure.

Wiring 250 is provided on the mounting surface of wiring substrate 240. The material, size and the like of wiring substrate 240 are not particularly limited, but for example, a printed substrate having an insulating layer formed of a generally used glass epoxy resin can be used. Wiring 250 is not particularly limited and can be formed in, for example, a copper foil pattern having a thickness of about 8 μm to 35 μm, inclusive.

In a conventional semiconductor-mounted product, a so-called underfill structure is employed in which a gap between a wiring substrate and a semiconductor package is filled with a filling material to completely fill the space without a gap. However, in the case of such a conventional underfill structure, it is difficult to completely fill the gap without a void when the number of bumps in the semiconductor package is large. For this reason, in the conventional underfill structure, the underfilling material may not be filled, and a void and the like may be generated when the number of bumps increases and the diameter of individual bumps decreases or the density of a large number of bumps increases.

On the other hand, in the case of semiconductor-mounted product 310, soldered portion 270 is surrounded and reinforced by resin-reinforced portion 290 as illustrated in FIG. 4A and FIG. 4B. Soldered portion 270 is formed as bumps 130 of semiconductor part 110 melt by reflow.

For example, when the number of bumps 130 of semiconductor part 110 increases, the diameter of bumps 130 decreases and a large number of bumps 130 are formed on mounting surface 150 of semiconductor part 110 at high density. As described above, even in a case in which bumps 130 are small and disposed at high density, resin-reinforced portion 290 uniformly reinforces the periphery of each soldered portion 270 in semiconductor-mounted product 310.

FIG. 4A and FIG. 4B illustrate a structure in which filling material 320 is provided at a corner portion and the like of semiconductor package 120. However, filling material 320 is not essential and may be applied if necessary. Here, filling material 320 is an insulating adhesive for increasing the adhesive strength between semiconductor package 120 and wiring substrate 240. As filling material 320, it is possible to use a known insulating material to be generally used in the formation of underfill, side fill, corner fill and the like. As insulating filling material 320 which links semiconductor package 120 to wiring substrate 240 is provided at the peripheral portion of semiconductor package 120 as illustrated in FIG. 4A and FIG. 4B, the connection reliability of semiconductor-mounted product 310 is improved. Incidentally, filling material 320 is not required to cover the entire periphery of semiconductor package 120 but may cover one or more sides of semiconductor package 120 or one or more corners of semiconductor package 120. Incidentally, filling material 320 and resin-reinforced portion 290 may be formed at the same time or filling material 320 may be formed after resin-reinforced portion 290 is formed.

In FIG. 4A, height 300 of resin-reinforced portion 290 is preferably 40% or more and more preferably 60% or more of height 280 of soldered portion 270. In addition, height 300 of resin-reinforced portion 290 may be 100% to be the same as height 280 of soldered portion 270 as illustrated in FIG. 8 to be described later. In addition, a part of mounting surface 150 of semiconductor package 120 may be covered with a part of resin-reinforced portion 290 as illustrated in FIG. 8 to be described later. Incidentally, height 300 of resin-reinforced portion 290 is the height obtained by subtracting the thickness of wiring 250, namely, the height from wiring 250.

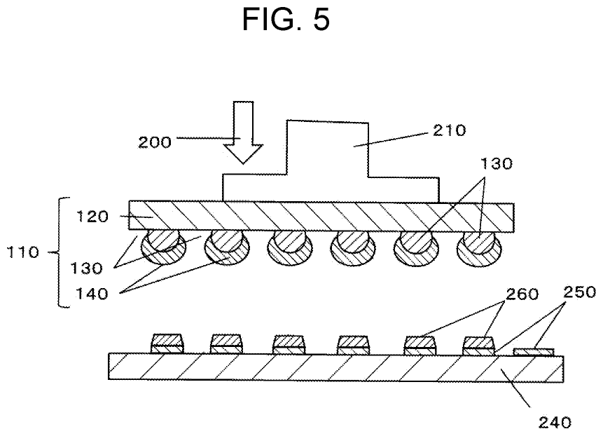

Next, an example of a method of manufacturing semiconductor-mounted product 310 is described with reference to FIG. 5 and FIG. 8. FIG. 5 is an explanatory view illustrating a procedure for mounting semiconductor part 110 on the surface of wiring substrate 240. FIG. 6 is an enlarged view of a main section in the procedure illustrated in FIG. 5. FIG. 7 is an enlarged cross-sectional view of a main section illustrating a state in which semiconductor part 110 is mounted on the surface of wiring substrate 240 by the procedure illustrated in FIG. 5 or FIG. 6 and reflow is not yet performed. FIG. 8 is an enlarged cross-sectional view of a main section of semiconductor-mounted product 310.

As illustrated in FIG. 5, the semiconductor-mounted product 310 is manufactured by mounting semiconductor part 110 on the mounting surface (namely, the surface on which wiring 250 is formed) of wiring substrate 240.

Arrow 200 indicates the direction in which semiconductor part 110 held by part holding tool 210 is mounted on wiring 250. It is preferable that solder paste 260 be disposed on wiring 250 in advance by printing and the like. As illustrated in FIG. 6, it is useful to use first composition 230b having the same composition as first composition 230a which constitutes covering portion 140 as solder paste 260.

In the example illustrated in FIG. 6, covering portion 140 is formed at the tip portion of bump 130 using first composition 230a containing solder powder 170a formed of second solder, a flux component, and first binder 160a. In addition, solder paste 260 is formed using first composition 230b containing solder powder 170b formed of second solder, a flux component, and first binder 160b. Incidentally, first composition 230b and first composition 230a may be the same as each other in composition or similar to each other in constituents.

Thereafter, semiconductor part 110 is moved in the direction indicated by arrow 200a in FIG. 6 and mounted on wiring substrate 240 on which solder paste 260 is formed to obtain a state illustrated in FIG. 7.

As indicated by arrow 200a in FIG. 7, bump 130 on which covering portion 140 is formed is mounted on solder paste 260 so as to be embedded. At this time, the part covering the tip of bump 130 of covering portion 140a is moved from the tip of bump 130 to the side surface of bump 130 by the reaction force of solder paste 260. Thereafter, the part covering the side surface of bump 130 of covering portion 140a is pushed up toward semiconductor package 120.

Auxiliary line 190a indicates the end position of covering portion 140 before bump 130 is mounted on solder paste 260. Auxiliary line 190b indicates the end position of covering portion 140 after bump 130 is mounted on solder paste 260.

Arrow 200b indicates the height (or dimension of change in height) of covering portion 140a swelled around bump 130 when bump 130 is pressed against the solder paste. The phenomenon (a kind of bulge phenomenon) in which covering portion 140a swells around bump 130 can be described as follows. In other words, covering portion 140a covering the surface of bump 130 is stripped off by solder paste 260 when bump 130 intrudes into solder paste 260. Thereafter, covering portion 140a stripped off swells around bump 130 as a kind of bulge by the height indicated by arrow 200b.

As bump 130 having covering portion 140a is mounted on solder paste 260 so as to be embedded in this manner, covering portion 140a covering bump 130 can be heightened from the position indicated by auxiliary line 190a to the position indicated by auxiliary line 190b by the height indicated by arrow 200b in FIG. 7.

Incidentally, the same effect is obtained even in a case in which a commercially available solder paste not containing a thermosetting resin binder is used as solder paste 260 to be provided on wiring 250. In other words, by carrying out the operation illustrated in FIG. 7, covering portion 140a covering bump 130 can be heightened from the position indicated by auxiliary line 190a to the position indicated by auxiliary line 190b by the height indicated by arrow 200b.

As described above, even when the height of covering portion 140 is about 40% of the height of bump 130 in a state in which mounting illustrated in FIG. 2A is not yet performed, the height of covering portion 140 becomes 50% or more of the height of bump 130 as illustrated in FIG. 7 when covering portion 140 is pressed onto solder paste 260.

Furthermore, when the solder reflow step is performed, covering portion 140a becomes still higher than that before reflow step is performed.

In the solder reflow step, the plurality of solder powders 170a contained in covering portion 140a melt and are integrated with one another. This melting and integration pushes first binder 160a from the inside to the outside of covering portion 140a. First binder 160a thus pushed to the outside covers the periphery of soldered portion 270 illustrated in FIG. 8. Moreover, first binder 160 pushed to the outside is accumulated around soldered portion 270 and the height of resin-reinforced portion 290 in semiconductor-mounted product 310 becomes from 40% to 100%, inclusive, of the height of soldered portion 270 from wiring 250.

Furthermore, as bump 130 melts and solder powder 170 and bump 130 are integrated with each other by the reflow step, the distance between wiring substrate 240 and semiconductor package 120 is decreased. In other words, height 280 after reflow is lower than that before reflow. As a result, even when the height of resin-reinforced portion 290 is the same before and after the reflow step, the relative height of resin-reinforced portion 290 is 50% or more of the height of soldered portion 270 from wiring 250.

Incidentally, in FIG. 6 and FIG. 7, as the same material composition or the same Bi-containing solder material is used in solder powder 170a and solder powder 170b, the melting temperatures thereof can coincide with each other. In addition, as the same resin material is used in first binder 160a and first binder 160b, the thermosetting behaviors thereof can be matched with each other. Alternatively, as similar resin materials compatible with each other are used in first binder 160a and first binder 160b, first binder 160a and first binder 160b are favorably mixed with each other and an interface is not formed therebetween.

Incidentally, solder plating and the like may be formed on wiring 250 instead of solder paste 260. In this case as well, first binder 160a is pushed to the outside of covering portion 140 as solder powder 170a melts into and is integrated with the molten solder plating at the time of reflow. Moreover, first binder 160a pushed out increases the height and thickness of resin-reinforced portion 290.

FIG. 8 is an enlarged cross-sectional view of a main section of the semiconductor-mounted product illustrated in FIG. 4A. On wetted surface 330, a part of mounting surface 150 of semiconductor package 120 is wetted with a part of resin-reinforced portion 290. The mounting strength is enhanced as first binder 160 constituting resin-reinforced portion 290 is also attached to mounting surface 150 on wetted surface 330 in this manner.

Through the above steps, semiconductor-mounted product 310 has the above-described solder joint structure constituted by semiconductor package 120, wiring substrate 240, soldered portion 270, and resin-reinforced portion 290 as illustrated in FIG. 4A and FIG. 8.

As illustrated in FIG. 8, soldered portion 270 includes first solder region 340 and second solder region 350. First solder region 340 is formed closer to semiconductor package 120 than wiring substrate 240 and second solder region 350 is formed closer to wiring substrate 240 than semiconductor package 120. First solder region 340 is derived from the first solder constituting bump 130. In addition, second solder region 350 is derived from the second solder constituting solder powder 170 contained in covering portion 140.

It is possible to use a Sn-Ag-Cu-based solder material (for example, a solder material called SAC 305) as the first solder constituting bump 130 as described above.

In addition, it is possible to use a Sn-Bi-based solder material containing Bi as an essential component as the second solder constituting solder powder 170. As second solder region 350 contains Bi, the wettability of soldered portion 270 to wiring 250 is enhanced. In addition, it is also useful to diffuse Ag and Cu components contained in Sn-Ag-Cu-based first solder region 340 into Sn-Bi-based second solder region 350. Bi is poorly elongated, and thus a problem may occur by drop impact and the like. In contrast, when a metal component such as Ag or Cu contained in the first solder diffuses into Sn-Bi-based second solder region 350, the ductility of solder alloy is ameliorated and the drop impact resistance is improved. Incidentally, as Ag and Cu diffuse into Sn-Bi-based second solder region 350, second solder region 350 may become Sn-Bi-Ag-Cu-based solder. Incidentally, these solder regions can be confirmed by a simple evaluation method using an X-ray microanalyzer and the like but it is not required to form a clear interface between the regions. Rather, it is desirable to form a diffusion layer between first solder region 340 and second solder region 350.

The strength of soldered portion 270 is enhanced as the periphery of the part containing Bi (for example, second solder region 350 in FIG. 8) is covered and reinforced with resin-reinforced portion 290 as illustrated in FIG. 8 and FIG. 18 to be described later. In other words, it is preferable that resin-reinforced portion 290 covers at least the side surface of second solder region 350 in a case in which second solder region 350 contains Bi.

It is useful to increase the average thickness of resin-reinforced portion 290 surrounding the periphery of second solder region 350 to 1 μm or more, further 5 μm or more, and 10 μm or more in a case in which second solder region 350 containing Bi is surrounded by resin-reinforced portion 290. The reinforcing effect may decrease in a case in which the average thickness is less than 1 μm.

In addition, it is preferable that resin-reinforced portion 290 covering the side surface of second solder region 350 extends from the side surface of second solder region 350 to the side surface of first solder region 340 and covers the side surface of first solder region 340 as illustrated in FIG. 8. Furthermore, it is preferable that resin-reinforced portion 290 continuously covers the part from the top of wiring substrate 240 to mounting surface 150 of semiconductor package 120 via the side surface of soldered portion 270. By forming resin-reinforced portion 290 long as these, soldered portion 270 and resin-reinforced portion 290 formed therearound become a kind of composite structural material. For this reason, even in a case in which semiconductor-mounted product 310 falls and the like, it is possible to diminish the concentration of the shock wave generated thereby on soldered portion 270. As soldered portion 270 and resin-reinforced portion 290 are combined with each other in this manner, it is possible to absorb a part of the energy of falling object generated at the time of falling by utilizing the difference in physical properties between the two (difference in stiffness, elastic modulus, glass transition temperature, loss elastic modulus, and the like).

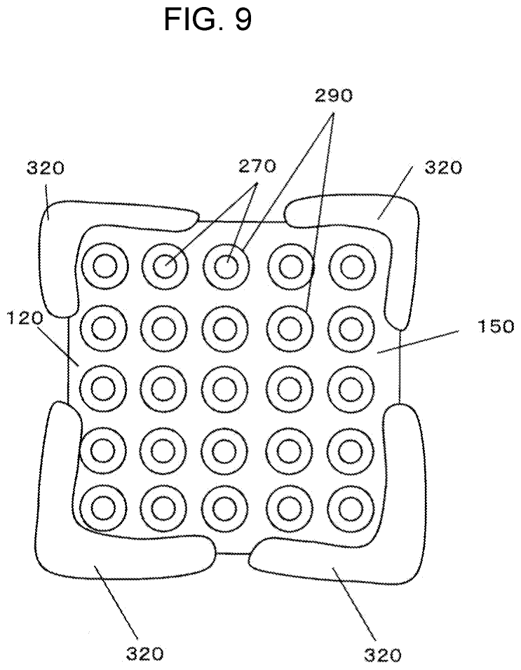

Next, a further preferred structure is described with reference to FIG. 9. FIG. 9 is a plan view schematically illustrating the mounting surface of the semiconductor-mounted product according to the present exemplary embodiment.

Resin-reinforced portion 290 may be formed on mounting surface 150 so as to surround each periphery of the plurality of soldered portions 270 in a ring shape of 360 degrees. In addition, the respective resin-reinforced portions 290 formed on the plurality of soldered portions 270 may be linked to one another on mounting surface 150.

In addition, the corner fill or the side fill formed of filling material 320 may be provided at the peripheral part and the like of semiconductor package 120 as described above. These greatly enhance the reliability of semiconductor mounted product 310. As filling material 320, it is possible to use an insulating material which is a filling material to be generally used and is obtained by adding an inorganic filler and the like to a thermosetting resin such as an epoxy resin.

Hereinafter, the effects of the present exemplary embodiment are described using a specific example of semiconductor part 110.

### (1) Sample E1 to Sample E4

As to be described below, semiconductor-mounted products according to sample E1 to sample E4 are fabricated and subjected to the evaluation on solder joint strength.

First, solder paste A containing solder powder 170 containing Bi, a flux component, and first binder 160 is prepared as first composition 230.

Sn42Bi58 manufactured by MITSUI MINING & SMELTING CO., LTD. is used as solder powder 170. An epoxy resin (“YD128” manufactured by NIPPON STEEL Chemical & Material Co., Ltd.) is used as uncured first binder 160. A phenol curing agent (“MEH-8000H” manufactured by MEIWA PLASTIC INDUSTRIES, LTD.) is used as a curing agent. Abietic acid is used as a flux component. Thereafter, 80.0 parts by mass of a solder powder, 16.4 parts by mass of an epoxy resin, 0.9 part by mass of a curing agent, and 2.7 parts by mass of a flux component are blended together and uniformly mixed and kneaded using a disperser. A paste-like first composition (solder paste A) is thus prepared.

Next, semiconductor part 110 illustrated in FIG. 1A is fabricated through the steps illustrated in FIG. 3A and FIG. 3B described above. Specifically, first, a BGA (package size: 14×14 mm, ball diameter: 0.45 mm, pitch: 0.8 mm) which is semiconductor package 120 having a plurality of bumps 130 on mounting surface 150 is prepared. Next, transfer table 220 having a concave pool is horizontally placed, and solder paste A is poured into this pool to form a smooth transfer surface of solder paste A. Thereafter, bumps 130 are directed downward and the upper surface of BGA which is semiconductor package 120 is held by part holding tool 210 in conformity to the method illustrated in FIG. 3A and FIG. 3B. Next, BGA is lowered toward transfer table 220 to bring bumps 130 into contact with the transfer surface while keeping mounting surface 150 parallel to the transfer surface of solder paste A. Solder paste A is thus attached to bumps 130. At this time, the depth at which bumps 130 are dipped in solder paste A is adjusted by increasing or decreasing the depth of solder paste A to be poured into transfer table 220. In this manner, four kinds of samples (sample E1 to sample E4) of semiconductor part 110 on which covering portion 140 which is formed of solder paste A and covers bumps 130 is formed are fabricated. The difference among sample E1 to sample E4 is the height of covering portion 140.

Semiconductor part 110 of each sample fabricated in this manner is mounted on wiring substrate 240 by the following procedure. First, FR-4 is prepared as a base material of wiring substrate 240 having wiring 250 on the mounting surface. FR-4 is a base material obtained by impregnating a glass fiber cloth with an epoxy resin, subjecting the impregnated glass fiber cloth to a thermosetting treatment, and molding the treated glass fiber cloth into a plate shape. A glass epoxy substrate is formed by sticking a copper foil on the surface using FR-4 as a base material. The thickness of wiring substrate 240 is 0.8 mm, and the diameter of electrode (land) is 0.4 mm. The first composition (solder paste A) is supplied to the electrode (land) of wiring 250 on wiring substrate 240 using a metal mask for printing. Incidentally, the opening diameter of the metal mask is 0.4 mm.

Thereafter, BGA provided with covering portion 140 and wiring substrate 240 are disposed, bump 130 and the electrode of wiring 250 are positioned, and BGA is mounted on wiring substrate 240 as illustrated in FIG. 5 described above. Thereafter, wiring substrate 240 on which BGA is mounted is heated in accordance with a predetermined heating profile to melt and solidify bumps 130 and to melt and integrate solder powder 170 with bumps 130. Soldered portion 270 for jointing wiring 250 and semiconductor package 120 is thus formed. At the same time, first binder 160 contained in the first composition is cured to form resin-reinforced portion 290 which reinforces soldered portion 270 from the periphery. According to the procedure described above, semiconductor-mounted products 310 of sample E1 to sample E4 are fabricated.

### (2) Sample C1 and Sample C2

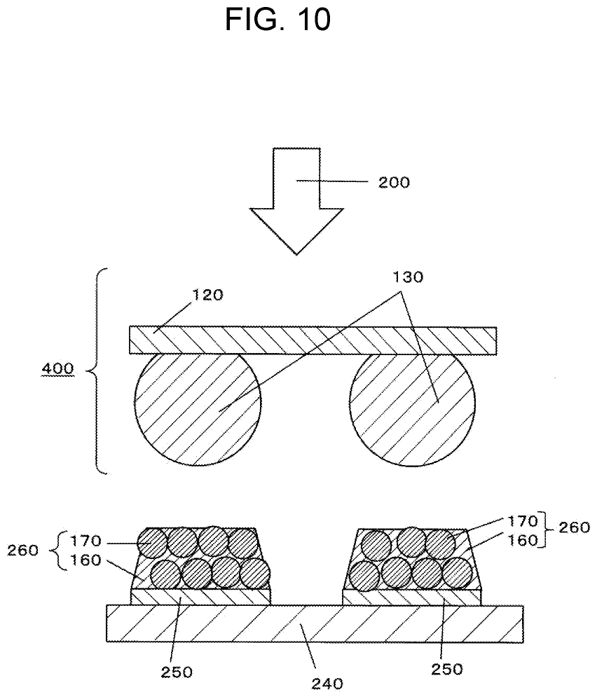

Next, sample C1 and sample C2 are described with reference to FIG. 10. FIG. 10 is a cross-sectional view for explaining the mounting procedure of a semiconductor part of sample C2. The sample C1 is fabricated as follows. A covering portion is not formed on the surface of bump 130 of BGA to be semiconductor package 120. In other words, BGA in a state in which solder paste A is not attached to the surface of the bump is used. In other words, semiconductor part 400 illustrated in FIG. 10 is used. On the other hand, commercially available solder paste B is prepared for metal mask printing. Solder paste B contains a flux but does not contain first binder 160. Thereafter, solder paste B is printed on the electrode of wiring 250 on wiring substrate 240. On the other hand, nothing is formed on the surface of bump 130. BGA is mounted on wiring substrate 240 in the same manner as in samples E1 to E4 except this. A semiconductor-mounted product of sample C1 is thus fabricated.

In sample C2, BGA to be semiconductor package 120 is used as semiconductor part 400 without forming covering portion 140 on bumps 130 in the same manner as in sample C1. However, solder paste A is used for metal mask printing. In other words, solder paste A is printed on the electrode of wiring 250 on wiring substrate 240. BGA is mounted on wiring substrate 240 in the same manner as in sample E1 to sample E4 except this. A semiconductor-mounted product of sample C2 is thus fabricated.

### (3) Evaluation on Reliability

Next, the contents and results of the evaluation on reliability performed for samples E1 to E4 and samples C1 and C2 are described.

### (3-1) Temperature Cycling Test

Semiconductor-mounted products 310 of sample E1 to sample E4 and semiconductor-mounted products of samples C1 and C2 are electrically inspected to be sorted into non-defective products, defective products, and the like. Thereafter, a heat cycle test in which the non-defective products are alternately immersed in a liquid bath at 40° C. for 5 minutes and in a liquid bath at 80° C. for 5 minutes is performed up to 1000 cycles.

### (3-2) Drop Test

Semiconductor-mounted products 310 of sample E1 to sample E4 and semiconductor-mounted products of samples C1 and C2 are electrically inspected to be sorted into non-defective products, defective products, and the like. Thereafter, the non-defective products are subjected to the evaluation to determine the number of drops until the instantaneous interruption occurs to the circuit of the semiconductor-mounted product under a condition of impact acceleration 1500 G/0.5 ms. The number of drops is set to a maximum of 1000 times.

The evaluation results by the tests described above are presented in (Table 1).

TABLE 1

| Sample | E1 | E2 | E3 | C1 | C2 | E4 |
|---|---|---|---|---|---|---|
| Solder paste on | A | A | A | B | A | A |
| electrode | | | | | | |
| Solder paste of | A | A | A | — | — | A |
| covering portion | | | | | | |
| Height of covering | 40 | 50 | 80 | 0 | 0 | 35 |
| portion (%) | | | | | | |
| Height of resin- | 50 | 65 | 100 | 0 | 30 | 45 |
| reinforced | | | | | | |
| portion (%) | | | | | | |
| Temperature | >1000 | >1000 | >1000 | 250 | 400 | 500 |
| cycling | cycles | cycles | cycles | cycles | cycles | cycles |
| Drop test | >1000 | >1000 | >1000 | 20 | 250 | 300 |
| | times | times | times | times | times | times |

Incidentally, solder paste A in (Table 1) corresponds to first composition 230 described in the first exemplary embodiment. The height of cover portion is the height indicated by arrow 200 in FIG. 2A and FIG. 2B. The height of resin-reinforced portion is height 300 indicated by the arrows in FIG. 4A and FIG. 8.

In sample E1 to sample E4, resin-reinforced portion 290 surrounds the entire periphery of soldered portion 270. As presented in (Table 1), height 300 of resin-reinforced portion 290 reaches a height to be 50% or more of height 280 of solder portion 270 particularly in sample E1 to sample E3 in which the height of covering portion 140 is 40% or more of the height of bump 130.

On the other hand, resin-reinforced portion 290 is not substantially formed in sample C1, and the height of the resin-reinforced portion is only 30% of the height of the soldered portion in sample C2.

In each of sample E1 to sample E3, 1000 cycles are cleared in the temperature cycling test and 1000 times are cleared in the drop test as well. In sample E4, the height of covering portion 140 is 35% to be lower than that in sample E1 to sample E3 and the height of resin-reinforced portion 290 is also less than 50%. As a result, the evaluation results on the temperature cycling test and the drop test are inferior to those for sample E1 to sample E3. However, the evaluation results are superior to those for sample C1 and sample C2. Sample E1 to sample E4 thus exhibit excellent mounting reliability

In sample C1, the resin-reinforced portion is not formed, thus a problem occurs after 250 cycles in the temperature cycling test and a problem occurs after 20 times in the drop test.

In sample C2, the height of the resin-reinforced portion is 30%, thus a problem occurs after 400 cycles in the temperature cycling test and a problem occurs after 250 times in the drop test.

As described above, in sample E1 to sample E4, resin-reinforced portion 290 is formed around soldered portion 270 after reflow, and favorable results re obtained in both the temperature cycling test and the drop test. From the evaluation results for sample E1 to sample E4, it is understood that the height of covering portion 140 is preferably 35% or more and more preferably 40% or more of the height of bump 130.

### (4) Investigation on Problem Occurred in Sample C2

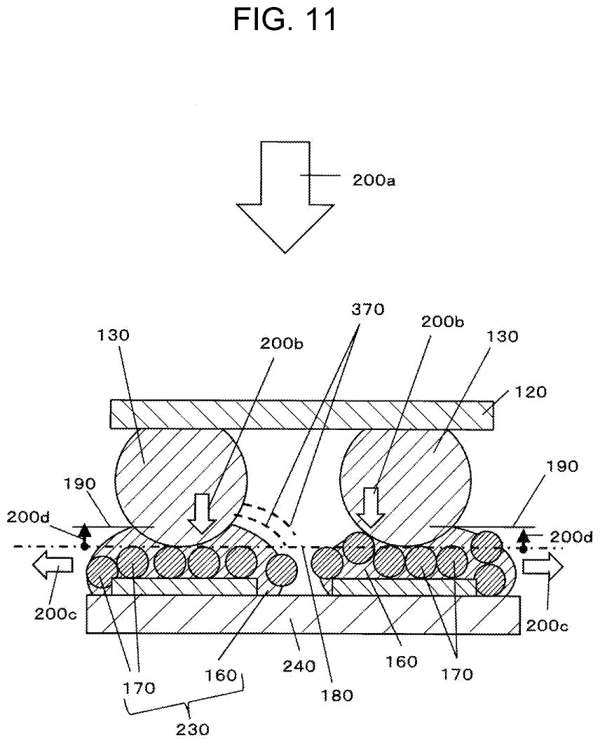

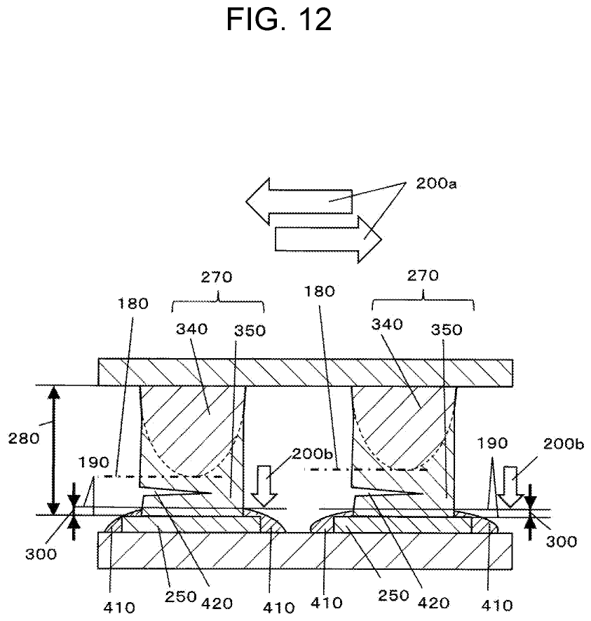

The problems occurred in sample C2 and the causes thereof are discussed below with reference to FIG. 10 to FIG. 12. FIG. 11 and FIG. 12 are cross-sectional views illustrating states before and after reflow of sample C2, respectively.

As described above, in semiconductor part 400 of sample C2 illustrated in FIG. 10, covering portion 140 is not present on the surface of bump 130.

Arrow 200a in FIG. 11 indicates the direction in which semiconductor package 120 is mounted on wiring substrate 240. Arrow 200b and dotted line 370 both indicate a situation that the solder paste or first composition 230 on wiring 250 is pressed against bump 130 and thinned. Arrow 200c indicates a situation that first composition 230 on wiring 250 is pushed to the outside of wiring 250 by being pushed by bump 130.

As illustrated in FIG. 11, there are few members swelling around bump 130 as a kind of bulge in the case of sample C2. For this reason, the height of the part constituted only by first binder 160 indicated by arrow 200d is low.

As illustrated in FIG. 12, the range in which resin-cured portion 410 covers soldered portion 270 is small. Specifically, the height of the resin-reinforced portion in sample C2 is 30% as presented in (Table 1). For this reason, crack 420 may be generated at soldered portion 270 which is not covered with resin-cured portion 410 in the drop test and the like as presented in (Table 1). Furthermore, crack 420 may often concentrates at the part containing a Bi component in the solder.

### (5) Sample E5 to Sample E10

Next, sample E5 to sample E10 which are other examples according to the present exemplary embodiment are described.

In sample E5 to sample E7, solder is not formed on the electrode of wiring 250. Moreover, the heights of covering portions 140 are 80%, 60%, and 40%, respectively, with respect to the height of bumps 130. Sample E5 to sample E7 are the same as sample E1 except this.

In sample E8, solder plating is formed on the electrode of wiring 250. The amount of solder is the same as that of solder powder 170. Moreover, the height of covering portion 140 is 60% of the height of bumps 130. Sample E8 is the same as sample E1 except this.

In sample E9, the height of covering portion 140 is 40% of the height of bumps 130. However, the thickness of covering portion 140 is two-fold that in sample E1. Sample E9 is the same as sample E1 except this.

In sample E10, above-described solder paste B is supplied onto the electrode of wiring 250. The height of covering portion 140 is 60% of the height of bumps 130. However, the thickness of covering portion 140 is three-fold that in sample E1. Sample E10 is the same as sample E1 except this.

The configurations and evaluation results for samples E5 to E10 are presented in (Table 2).

TABLE 2

| Sample | E5 | E6 | E7 | E8 | E9 | E10 |
|---|---|---|---|---|---|---|
| Solder paste on | — | — | — | Solder | A | B |
| electrode | | | | plating | | |
| Solder paste of | A | A | A | A | A | A |
| covering portion | | | | | | |
| Ratio of | 1 | 1 | 1 | 1 | 2 | 3 |
| thickness | | | | | | |
| Height of covering | 80 | 60 | 40 | 60 | 40 | 60 |
| portion (%) | | | | | | |
| Height of resin- | 100 | 100 | 60 | 100 | 100 | 100 |
| reinforced | | | | | | |
| portion (%) | | | | | | |
| Temperature | >1000 | >1000 | >1000 | >1000 | >1000 | >1000 |
| cycling | cycles | cycles | cycles | cycles | cycles | cycles |
| Drop test | >1000 | >1000 | >1000 | >1000 | >1000 | >1000 |
| | times | times | times | times | times | times |

As presented in (Table 2), in sample E5 to sample E10, the height of resin-reinforced portion 290 is 60% or more of the height of soldered portion 270 and favorable results are obtained in the temperature cycling test and the drop test by setting the height of covering portion 140 to 40% or more.

From the results for sample E5 to sample E7, it is understood that the height of covering portion 140 with respect to the height of bumps 130 may be set to 40% or more and the height of resin-reinforced portion 290 may be set to 60% or more of the height of soldered portion 270 even when solder is not formed on the electrodes of wiring 250.

From the result for sample E8, it is understood that the height of resin-reinforced portion 290 is 100% of the height of soldered portion 270 and favorable results are obtained in the temperature cycling test and the drop test if the height of covering portion 140 is 60% of the height of bumps 130 even in a case in which the solder plating is formed on wiring 250.

It is considered that the reason for this is because first binder 160 contained in covering portion 140 is pushed to the outside of soldered portion 270 when the solder plating melts and solder powder 170 contained in covering portion 140 and the molten solder plating are integrated with each other. In other words, it is considered that first binder 160 pushed to the outside forms resin-reinforced portion 290 along the side surface of bump 130.

In addition, from the results for sample E9 and sample E10, it is understood that the height of resin-reinforced portion 290 is high to be 100% of the height of soldered portion 270 in the samples subjected to thick printing so that the thickness of solder paste A becomes thicker.

For example, in sample E9, the height of covering portion 140 is 40% of the height of bump 130, but the height of resin-reinforced portion 290 becomes 100% of the height of soldered portion 270 by increasing the amount of solder paste A and thickening covering portion 140. As a result, it is considered that favorable results are obtained in the temperature cycling test and the drop test.

Incidentally, it is useful to repeat the steps illustrated in FIG. 3A and FIG. 3B and to carry out the steps to be described with reference to FIG. 14 in the second exemplary embodiment in order to increase the thickness of solder paste A to 10 μm or more and further to 20 μm or more. It is useful to set the thickness of the region part covering the tip portion of bump 130 in covering portion 140 to 10 μm or more, 20 μm or more, and further 30 μm or more.

In sample E10, it is considered that the solder component of solder paste B is integrated with solder powder 170 contained in covering portion 140 in the reflow step and first binder 160 is pushed up along the side surface of bump 130. For this reason, the height of resin-reinforced portion 290 is high to be 100% of the height of soldered portion 270. As a result, favorable results are obtained in the temperature cycling test and the drop test. In addition, thick solder paste A on the surface of bumps 130 also contributes to an increase in the amount of first binder 160 and an increase in the height of resin-reinforced portion 290.

### Second Exemplary Embodiment

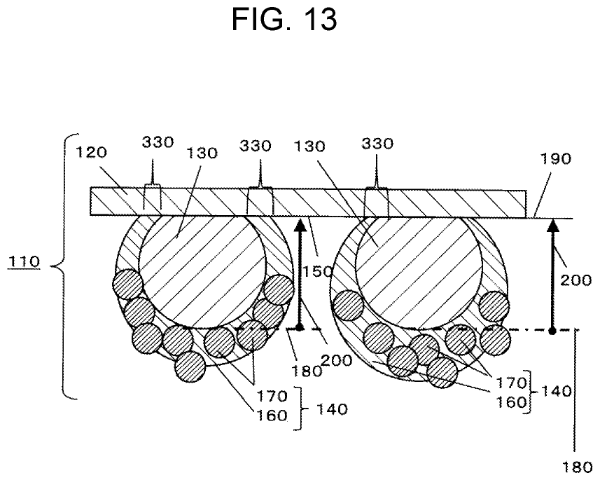

FIG. 13 is a cross-sectional view of semiconductor part 110 according to a second exemplary embodiment of the present invention. In semiconductor part 110 according to the present exemplary embodiment, covering portion 140 is formed until to reach mounting surface 150 of semiconductor package 120. The configuration other than this is the same as that of the first exemplary embodiment.

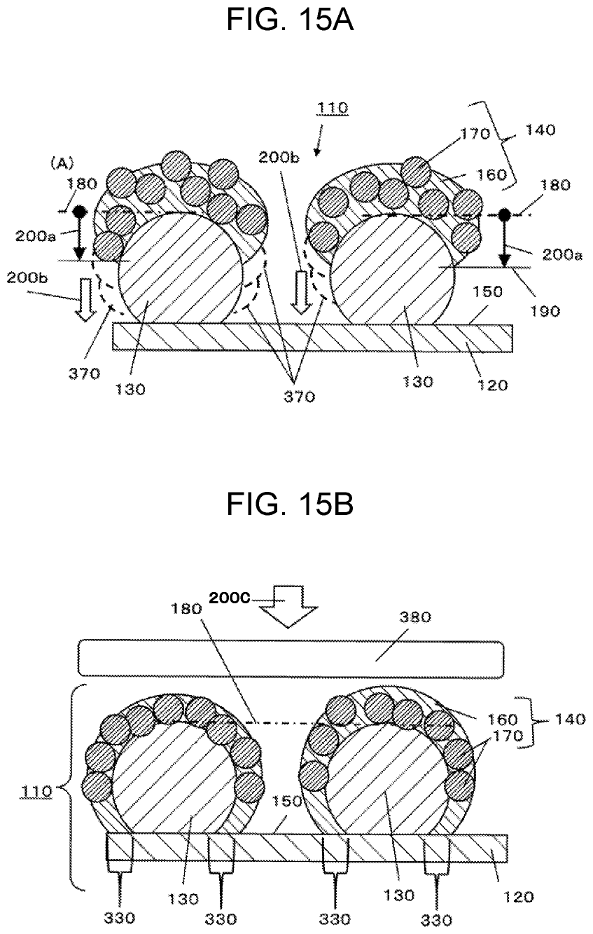

Covering portion 140 covering the surface of bump 130 is attached to mounting surface 150 as well. In this case, the transfer method described based on FIG. 3A and FIG. 3B is not suitable in order to form covering portion 140 on the surface of bump 130. In the case of applying the above-described transfer method, it is required to bring the transfer surface of first composition 230 accumulated in the pool of transfer table 220 into contact not only with the surface of bump 130 but also with mounting surface 150. However, covering portions 140 of the plurality of bumps 130 are all linked to one another when the operation is performed in such a manner. Hence, in order to manufacture semiconductor part 110 according to the present exemplary embodiment, for example, the steps illustrated in FIG. 14 to FIG. 15B may be performed. FIG. 14 is an explanatory view of a method of manufacturing semiconductor part 110 illustrated in FIG. 13. FIG. 15A and FIG. 15B are cross-sectional views of a main section for explaining a manufacturing procedure of semiconductor part 110 illustrated in FIG. 13.

As illustrated in FIG. 14, a plurality of recesses are formed at the positions corresponding to bumps 130 in accordance with the shape of bumps 130 on the upper part of first jig 360. Each of these recesses is formed in a size that can accommodate individual bumps 130. Moreover, as indicated by arrow 200a, liquid first composition 230 can be scooped from transfer table 220 and transferred onto the surface of bump 130 by moving first jig 360 up and down. First composition 230 can be formed on the side surface of bump 130 and the upper side than the center of bump 130 as covering portion 140 by forming the surface in contact with bump 130 of first jig 360 into a pan shape which coincides with the shape of bump 130.

In addition, as indicated by arrow 200b, covering portion 140 attached to the surface of bump 130 may be allowed to flow toward semiconductor package 120 by its own weight by inverting the top and bottom of semiconductor part 110. Such flow of covering portion 140 (first composition 230) is described with reference to FIG. 15A and FIG. 15B.

Arrow 200b and dotted line 370 in FIG. 15A indicate a situation that covering portion 140 covering bump 130 with the tip portion of bump 130 facing upward flows downward along the side surface of bump 130. In this manner, covering portion 140 flows toward semiconductor package 120 by its own weight. At this time, a part of first binder 160 may be attached to mounting surface 150 as illustrated in FIG. 15B.

Incidentally, the flow of covering portion 140 may be promoted by moving second jig 380 in the direction of arrow 200c and pressing second jig 380 against the tip portion of bump 130 as illustrated in FIG. 15B if necessary. As second jig 380, non-adhesive polytetrafluoroethylene or silicone rubber can be used. The elasticity and non-adhesive property of silicone rubber and the like are likely to promote the flow of covering portion 140. Alternatively, the flow of covering portion 140 may be promoted by the pressure of air generated using a fan and the like instead of second jig 380.

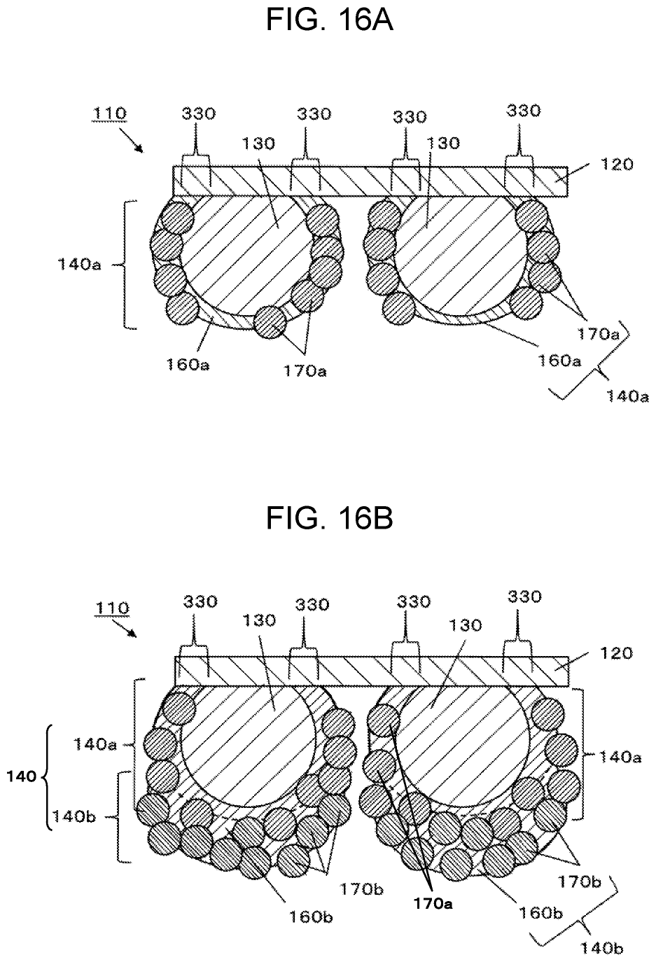

Next, the amount of covering portion 140 is described with reference to FIG. 16A and FIG. 16B. FIG. 16A and FIG. 16B are cross-sectional views of a main section of semiconductor part 110 according to the present exemplary embodiment in which the amount of covering portion 140 is different from each other.

As illustrated in FIG. 16A, the average thickness of first binder 160a formed on bumps 130 and the distribution of solder powder 170a may change in a case in which covering portion 140a formed on bump 130 is allowed to flow until the vicinity of semiconductor package 120. In such a case, first composition may be supplied by coating and the like so as to be superimposed on covering portion 140a and covering portion 140b may be thus further formed as illustrated in FIG. 16B. In other words, covering portion 140b may be layered on covering portion 140a. By repeating such a step, the size and volume of covering portion 140 can be increased and the variation thereof can be diminished.

Incidentally, as covering portion 140b to be superimposed on covering portion 140a, the first composition may be used but a composition in which the thermosetting resin binder has the same or similar component composition as that in the first composition may be supplied. Alternatively, covering portion 140b may be formed using a mixed composition of the first thermosetting resin binder with the flux component or using only the first thermosetting resin binder. As covering portion 140b is formed in this manner, covering portion 140a and covering portion 140b are favorably mixed with each other at the part at which both of these overlap each other and the interface between covering portion 140a and covering portion 140b disappears. As a result, firm resin-reinforced portion 290 at which cracking due to the interface hardly occurs is formed so as to cover approximately the entire outer periphery of soldered portion 270. In the same manner, the formation of solder portion 270 is stabilized as solder powder 170a contained in covering portion 140a and solder powder 170b contained in covering portion 140b have the same or similar component composition.

### Third Exemplary Embodiment

FIG. 17 is a cross-sectional view of a main section of semiconductor part 110 according to a third exemplary embodiment of the present invention. FIG. 18 is an enlarged cross-sectional view for schematically explaining a solder joint structure of semiconductor-mounted product 310 according to the present exemplary embodiment.

Semiconductor part 110 according to the present exemplary embodiment includes auxiliary covering portion 440 in addition to semiconductor part 110 according to the first exemplary embodiment illustrated in FIG. 2A and FIG. 2B. Auxiliary covering portion 440 covers a region which is not covered with covering portion 140 in the surface of bump 130. In other words, auxiliary covering portion 440 covers at least a region exposed from covering portion 140 of bump 130. Auxiliary covering portion 440 is formed of second composition 390 which contains second thermosetting resin binder (hereinafter, second binder) 430 and does not contain solder powder 170. The configuration other than this is the same as that of the first exemplary embodiment.

Covering portion 140 is formed so as to cover the region of at least the tip portion of bump 130, for example, as illustrated in FIG. 2A. For this reason, the surface of bump 130 which is not covered with covering portion 140 means a region from the end position of covering portion 140 indicated by auxiliary line 190 to mounting surface 150 of semiconductor part 110 in FIG. 2A. Hence, auxiliary covering portion 440 covers a region closer to mounting surface 150 on the side surface of bump 130.

Auxiliary covering portion 440 does not contain solder powder 170. Hence, as illustrated in FIG. 17, auxiliary covering portion 440 may be provided so as to extend from the side surface of bump 130 to mounting surface 150, and further auxiliary covering portions 440 provided on two adjacent bumps 130 may be in contact with each other to be linked. Even in this case, two adjacent bumps 130 do not conduct. Rather, it is preferable that auxiliary covering portion 440 extends from the side surface of one bump 130 to mounting surface 150 and further is linked to auxiliary covering portion 440 of adjacent bump 130. By this configuration, a stronger resin-reinforced structure can be realized. Of course, adjacent auxiliary covering portions 440 may be apart from each other and independent of each other.

At the time of reflow, the viscosity of auxiliary covering portion 440 decreases. Moreover, auxiliary covering portion 440 is integrated with the molten material of first binder 160 of covering portion 140 and constitutes resin-reinforced portion 290 surrounding the side surface of solder portion 270 as illustrated in FIG. 18. In other words, as auxiliary covering portion 440 is present, resin-reinforced portion 290 which covers the entire periphery of solder portion 270 can be more reliably formed.

Incidentally, a part of auxiliary covering portion 440 and a part of covering portion 140 may overlap each other. This overlapping facilitates the integration of first binder 160 of covering portion 140 melted at the time of reflow and second binder 430 of auxiliary covering portion 440 and makes it possible to more reliably form resin-reinforced portion 290.

Next, second composition 390 is described in more detail. Second binder 430 contained in second composition 390 is present in an uncured or B-stage state in the form of auxiliary covering portion 440. Moreover, second binder 430 is cured together with first binder 160 to constitute resin-reinforced portion 290 after being melted at the time of reflow.

The material for second binder 430 is not particularly limited as long as it can constitute resin-reinforced portion 290, but it is preferable to contain an epoxy resin and a curing agent as main components in the same manner as in first binder 160. Examples of the epoxy resin and curing agent which can be used include those the same as the compounds exemplified in the description of first binder 160. Furthermore, it is preferable that first binder 160 and second binder 430 are composed of the same material or similar resin materials compatible with each other. By this, first binder 160 and second binder 430 are favorably mixed with each other at the part at which auxiliary covering portion 440 and covering portion 140 overlap each other and the like.

Second composition 390 does not contain solder powder 170 and thus may contain a flux component, if necessary, although the flux component is not essential. In addition to the components described above, second composition 390 may contain, if necessary, modifiers, additives and the like in the same manner as first composition 230.

Next, a method of manufacturing semiconductor part 110 according to the present exemplary embodiment is described with reference to FIG. 19A to FIG. 19C. FIG. 19A to FIG. 19C are cross-sectional views of a main section for explaining a manufacturing procedure of semiconductor part 110 according to the present exemplary embodiment.

In order to attach second composition 390 to bumps 130 of semiconductor package 120, the following method and the like may be mentioned. For example, second composition 390 can be attached to bumps 130 by applying the steps illustrated in FIG. 3A and FIG. 3B. In other words, in FIG. 3A and FIG. 3B, the concave pool provided on transfer table 220 is filled with first composition 230, but second composition 390 is used instead of first composition 230. Moreover, second composition 390 can be attached from the tip portion to the side surface of bumps 130 by dipping bumps 130 of semiconductor package 120 in second composition 390. Alternatively, the step illustrated in FIG. 14 may be applied.

Next, as illustrated in FIG. 19A, second composition 390 attached to bump 130 with the tip portion of bump 130 facing upward is allowed to flow downward along the side surface of bump 130. In this manner, second composition 390 flows toward mounting surface 150 of semiconductor package 120 by its own weight. This makes it possible to cover the region closer to mounting surface 150 on the side surface of bump 130 with auxiliary covering portion 440 as illustrated in FIG. 19B. Incidentally, mounting surface 150 may also be continuously covered with auxiliary covering portion 440. In addition, auxiliary covering portions 440 formed on the respective bumps 130 may be linked to each other on mounting surface 150.

Incidentally, the viscosity, thixotropy, tack and the like may be adjusted in order to optimize the fluidity of second composition 390. For this, a thermoplastic resin, an additive, and an insulating additive such as an inorganic filler may be appropriately added to second composition 390.

Thereafter, the tip portion of bump 130 on which auxiliary covering portion 440 is formed is directed downward as illustrated in FIG. 19C. Moreover, first composition 230 is supplied to the surface of bump 130 and covering portion 140 is thus form as illustrated in FIG. 17.

Specifically, the intermediate in the state of FIG. 19C is subjected to the operations illustrated in FIG. 3A, FIG. 3B, and FIG. 14. In this manner, first composition 230 is attached from the tip portion to the side surface of bump 130 and covering portion 140 is thus formed as illustrated in FIG. 17. Incidentally, covering portion 140 may be formed so that covering portion 140 and auxiliary covering portion 440 partially overlap each other as described above. In addition, as auxiliary covering portion 440 covers the region which is not covered with covering portion 140 in bump 130 so as to complement covering portion 140, the entire outer periphery region of solder portion 270 can be covered with firm resin-reinforced portion 290.

Incidentally, the operation to form auxiliary covering portion 440 illustrated in FIG. 19A to FIG. 19C and the operation to form covering portion 140 may be carried out by reversing the order thereof. A part of covering portion 140 is formed on a part of auxiliary covering portion 440 when covering portion 140 and auxiliary covering portion 440 are formed in this manner. In other words, the region which is not covered with covering portion 140 in bump 130 may be covered with auxiliary covering portion 440.

By mounting semiconductor part 110 illustrated in FIG. 17 as illustrated in FIG. 6 to FIG. 7 described above, semiconductor-mounted product 310 illustrated in FIG. 18 can be formed. Resin-reinforced portion 290 illustrated in FIG. 18 is formed as first binder 160 contained in first composition 230 and second binder 430 contained in second composition 390 are favorably mixed with each other, cured, and integrated with each other without an interface therebetween.

### Fourth Exemplary Embodiment

As described in the first exemplary embodiment with reference to FIG. 8, it is preferable that the height of resin-reinforced portion 290 (the height of the part most distant from wiring 250 of resin-reinforced portion 290) is from 40% to 100%, inclusive, of the height of soldered portion 270 from wiring 250. However, as illustrated on the right side of FIG. 8, another problem related to reliability may occur when the height of resin-reinforced portion 290 is 100% of the height of soldered portion 270 over the entire periphery of soldered portion 270.

The solder contained in soldered portion 270 is remelted when soldered portion 270 is reheated. The solder expands as compared to that before being melted when the solder is remelted in this manner. Furthermore, such reheating causes warpage of wiring substrate 240. As a result of these, the pressure of the remelted solder increases. If resin-reinforced portion 290 has a part at which the adhesion with semiconductor package 120 or wiring substrate 240 is weak, the remelted solder is pushed out from this part and, in some cases, causes defects such as short. Hereinafter, such a phenomenon is called solder flash.

In order to suppress the solder flash, resin-reinforced portion 290 may be formed so that the height of resin-reinforced portion 290 does not become 100% of the height of solder portion 270 over the entire periphery of solder portion 270. In such a state, the remelted solder is released at the part which is not covered with resin-reinforced portion 290 and thus the pressure of the remelted solder does not increase significantly. As a result, solder flash can be suppressed.

Specifically, the solder flash can be suppressed by the following method. By regulating the amount of first binder 160a and/or first binder 160b, the height of resin-reinforced portion 290 is controlled to be less than 100% of the height of solder portion 270 as in sample E1 to sample E4 in (Table 1) and sample E7 in (Table 2). More specifically, the amount of the flux component contained in the first binder is controlled.

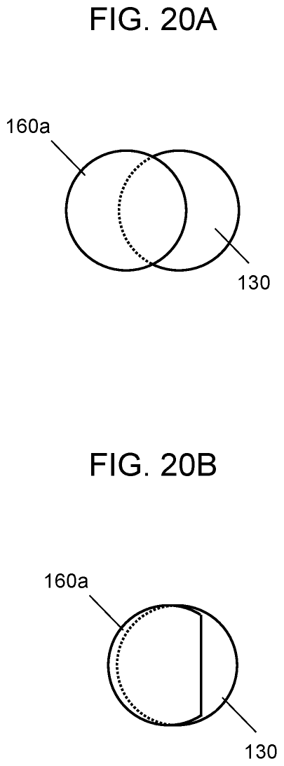

The solder flash can be suppressed by methods other than this. Hereinafter, a specific example thereof is described with reference to FIG. 20A and FIG. 20B. FIG. 20A and FIG. 20B are plan views illustrating the shapes of and positional relationship between bump 130 and first binder 160a when bump 130 is coated with first binder 160a in the present exemplary embodiment.

In the example illustrated in FIG. 20A, first binder 160a is supplied to bump 130 so that the center of first binder 160a is shifted from the center of bump 130. On the other hand, in the example illustrated in FIG. 20B, first binder 160a is supplied to bump 130 in a shape in which a part of the outer periphery of first binder 160a is missing. By supplying first binder 160a to bump 130 in a biased state in this manner, resin-reinforced portion 290 can be formed so that the heights thereof are different from each other on the left side and the right side in the drawing. In other words, resin-reinforced portion 290 can be formed so as to be lower on the right side than on the left side of bump 130. Incidentally, the arc part of first binder 160a is on the outer side than bump 130 in FIG. 20B but may coincide with the outer periphery of bump 130.

Incidentally, supply of first binder 160a to bump 130 as illustrated in FIG. 20A and FIG. 20B can be realized by, for example, covering bump 130 with a mask and printing first binder 160a through the holes formed on the mask. In this case, the center of the hole provided on the mask is shifted from the center of bump 130. Alternatively, the hole is formed in a shape in which a part of a circle is missing.

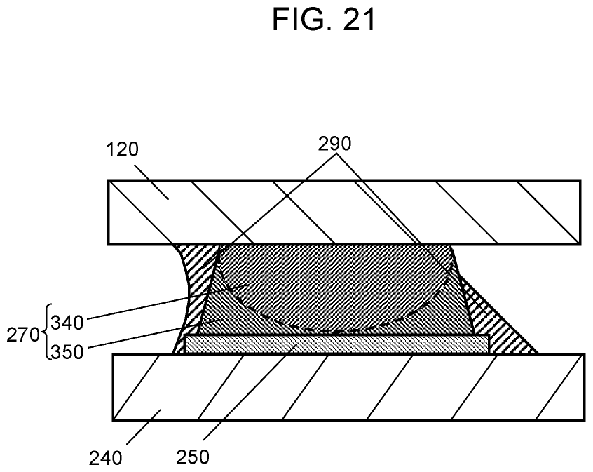

The effect of reinforcing solder portion 270 is higher as resin-reinforced portion 290 is higher as described above. In particular, it is preferable that the height of resin-reinforced portion 290 is 100% of solder portion 270 and resin-reinforced portion 290 is provided substantially from wiring substrate 240 to semiconductor package 120. For this reason, it is preferable that a part of resin-reinforced portion 290 continuously covers the part from the top of wiring substrate 240 to the mounting surface of semiconductor package 120 via the side surface of solder portion 270 at the entire periphery of solder portion 270 as illustrated in FIG. 21. The configuration other than this is the same as those of other exemplary embodiments.

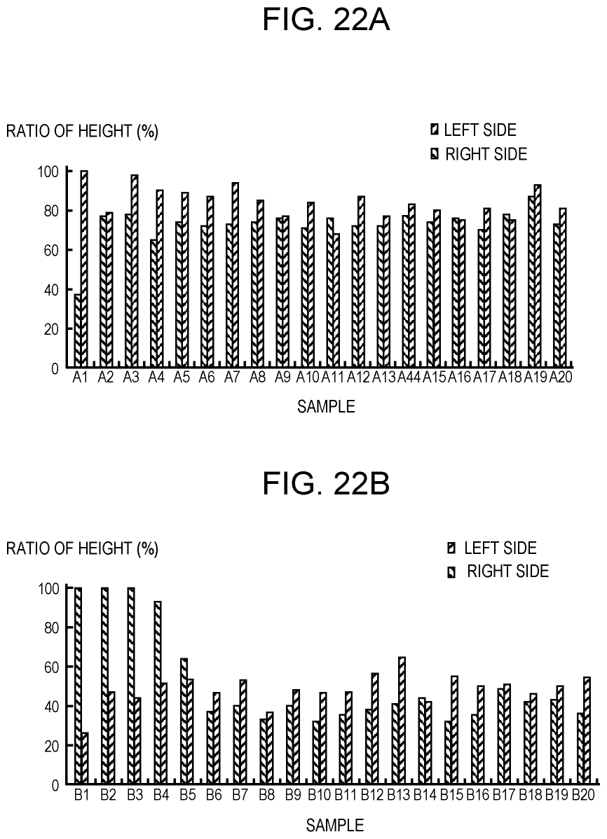

FIG. 22A is a view illustrating heights of left and right resin-reinforced portions 290 in various examples in which solder portion 270 is fabricated by first binder 160a illustrated in FIG. 20A, and FIG. 22B is a view illustrating heights of left and right resin-reinforced portions 290 in various examples in which solder portion 270 is fabricated by further shifting the center from the center of bump 130 than first binder 160a illustrated in FIG. 20A. In both cases, solder flash does not occur even in a case in which 300 pieces of samples are fabricated and reheated to 250° C. On the other hand, a sample in which first binder 160a is supplied to bump 130 so that the center of first binder 160a coincides with the center of bump 130 and the height of resin-reinforced portion 290 is 100% of the height of solder portion 270 over the entire periphery of solder portion 270 has a structure illustrated on the right side of FIG. 8. Solder flash occurs in 5 pieces in a case in which 300 pieces of samples are fabricated and reheated to 250° C.

Incidentally, in FIG. 22A, sample A1, sample A3, and sample A19 have a relatively high coverage of solder portion 270 by resin-reinforced portion 290. In addition, in FIG. 22B, sample B2 has a relatively high coverage of solder portion 270 by resin-reinforced portion 290. In the respective samples, the heights of the left and right of resin-reinforced portion 290 with respect to that of solder portion 270 are 38% and 100% in sample A1, 79% and 98% in sample A3, 86% and 91% in sample A19, and 100% and 48% in sample B2, respectively. Incidentally, the heights of the left and right of resin-reinforced portion 290 may be, for example, 100% and 99% since it is only required that a slight part of solder portion 270 is exposed from resin-reinforced portion 290 in principle.

Incidentally, in the description with reference to FIG. 20A and FIG. 20B, the case in which first binder 160a is applied to bump 130 has been described, but the shape and position of first binder 160b to be applied to wiring 250 may be controlled.

### Fifth Exemplary Embodiment

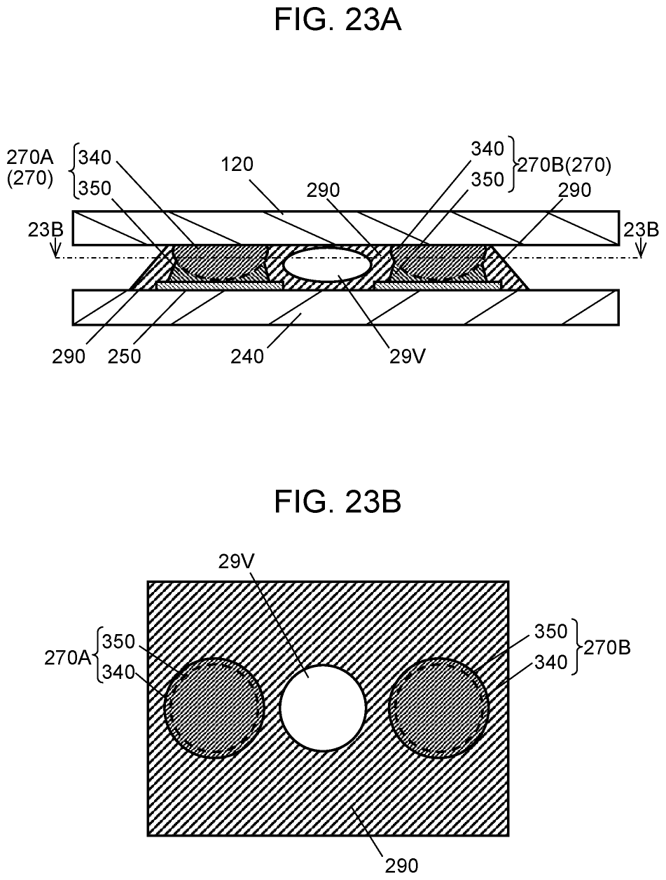

FIG. 23A is a longitudinal sectional view of a semiconductor-mounted product according to a fifth exemplary embodiment of the present invention, and FIG. 23B is a transverse sectional view taken along line 23B-23B in FIG. 23A. This semiconductor-mounted product includes semiconductor package 120, wiring substrate 240, a plurality of soldered portions 270, and resin-reinforced portion 290. Wiring 250 is formed on the surface of wiring substrate 240, and semiconductor package 120 is mounted on wiring substrate 240. The plurality of solder portions 270 include first soldered portion 270A and second soldered portion 270B adjacent to first soldered portion 270A. Hereinafter, first solder portion 270A and second soldered portion 270B are referred to as solder portions 270A and 270B. The plurality of solder portions 270 each electrically connect semiconductor package 120 to wiring 250. In addition, each of solder portions 270 has first solder region 340 formed closer to semiconductor package 120 than wiring substrate 240 and second solder region 350 formed closer to wiring substrate 240 than semiconductor package 120.

Resin-reinforced portion 290 is formed on the side surface of each of the plurality of soldered portions 270 and is also formed on wiring substrate 240 by linking soldered portion 270A to soldered portion 270B. In addition, space 29V in which resin-reinforced portion 290 is not present is provided between soldered portion 270A and soldered portion 270B.

A semiconductor mounted product having such a configuration is hardly damaged even in the case of being accidentally dropped since space 29V absorbs the impact. In addition, even when the semiconductor-mounted product is exposed to an environment in which the temperature periodically changes, space 29V can relieve the stress generated at this time. Moreover, resin-reinforced portion 290 is also formed on wiring substrate 240 by linking soldered portion 270A to soldered portion 270B, thus the rigidity of soldered portions 270A and 270B is improved and the drop resistance is further improved.

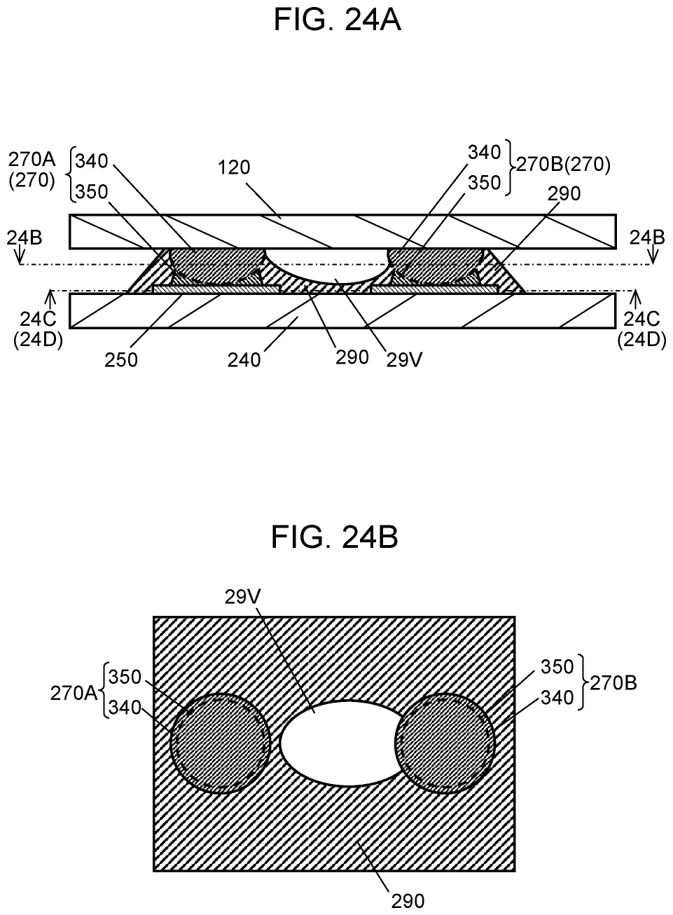

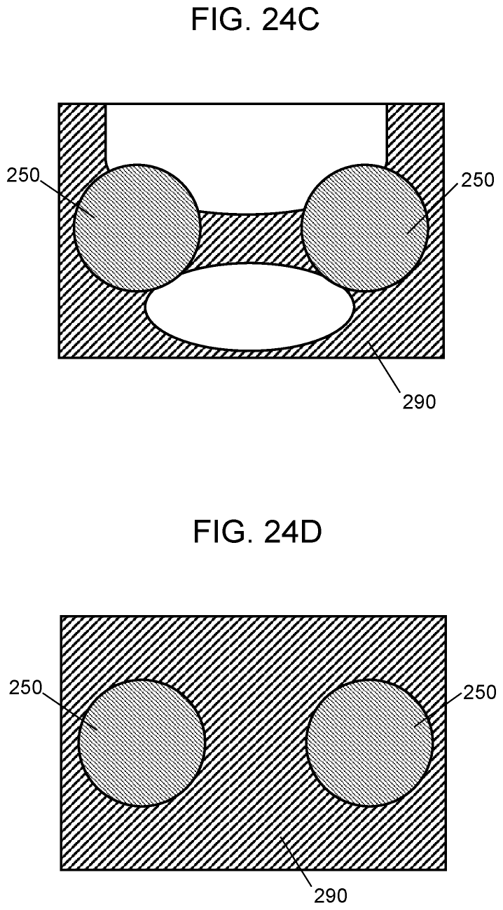

Incidentally, in FIG. 23A, resin-reinforced portion 290 is also formed on the mounting surface of semiconductor package 120 by linking soldered portion 270A to soldered portion 270B. Such a structure further contributes to the improvement in the rigidity of soldered portions 270A and 270B, but resin-reinforced portion 290 may not be necessarily formed on the mounting surface of semiconductor package 120. In other words, as illustrated in FIG. 24A and FIG. 24B, resin-reinforced portion 290 may not be formed on the mounting surface of semiconductor package 120. FIG. 24A is a longitudinal sectional view of another semiconductor-mounted product according to the present exemplary embodiment, and FIG. 24B is a transverse sectional view taken along line 24B-24B in FIG. 24A.

As described above, in soldered portion 270, second solder region 350 contains Bi and has a low melting point and thus the mechanical strength thereof is lower than that of first solder region 340. For this reason, from the viewpoint of improving rigidity, resin-reinforced portion 290 may be formed on the side surface of each of soldered portions 270 and may also be formed on the mounting surface of semiconductor package 120 by linking soldered portion 270A to soldered portion 270B.

In addition, it is preferable that the height of the part most distant from wiring 250 of resin-reinforced portion 290 is from 30% to 100%, inclusive, of the height of soldered portion 270 from wiring 250. Resin-reinforced portion 290 links soldered portion 270A to soldered portion 270B, and thus drop resistance can be secured even when the height of resin-reinforced portion 290 is 30% of the height of soldered portion 270. In this case as well, it is preferable that resin-reinforced portion 290 covers at least the side surface of second solder region 350. In addition, it is preferable from the viewpoint of strength that resin-reinforced portion 290 extends from the side surface of second solder region 350 to the side surface of first solder region 340 and covers the side surface of first solder region 340.

In addition, it is also preferable from the viewpoint of strength that a part of resin-reinforced portion 290 continuously covers the part from the top of wiring substrate 240 to the mounting surface of semiconductor package 120 via the side surface of soldered portion 270. On the other hand, if the height of resin-reinforced portion 290 is less than 100% of the height of soldered portion 270, the insulation failure due to the solder flash can be suppressed in the same manner as in the fourth exemplary embodiment.

In addition, insulating filling material 320 which links semiconductor package 120 to wiring substrate 240 may be provided at the peripheral portion of semiconductor package 120 in the same manner as that illustrated in FIG. 9.

FIG. 24C and 24D illustrate examples of cross sections passing through wiring 250 in FIG. 24A. As illustrated in FIG. 24C, resin-reinforced portion 290 may link two adjacent wirings 250 to each other and there may be a region in which resin-reinforced portion 290 is not provided around wiring 250. Alternatively, resin-reinforced portion 290 may cover the entire periphery of two adjacent wirings 250 as illustrated in FIG. 24D.

The formation of resin-reinforced portion 290 in this manner can be realized by lowering the viscosity of first binder 160a illustrated in FIG. 6 and enhancing the thixotropy. In other words, a material having a low viscosity and high thixotropy may be used as first binder 160a or the temperature may be raised at the time of reflow as illustrated in FIG. 7 to FIG. 8.

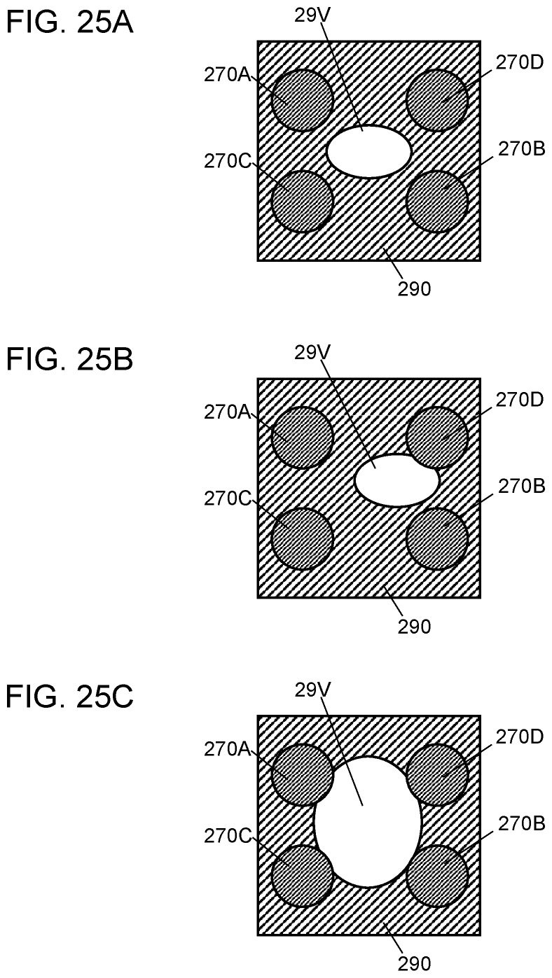

FIG. 25A and FIG. 25B illustrate cross sections in a case in which third solder joint 270C and fourth soldered portion 270D which surround space 29V together with soldered portions 270A and 270B are further included as soldered portion 270. Hereinafter, third solder joint 270C and fourth soldered portion 270D are referred to as soldered portions 270C and 270D.

In the example illustrated in FIG. 25A, soldered portions 270A, 270B, 270C, and 270D are all covered with resin-reinforced portion 290 without being exposed to space 29V. This configuration is preferable from the viewpoint of strength.

On the other hand, only soldered portion 270D is exposed to space 29V in the example illustrated in FIG. 25B, and soldered portions 270A, 270B, 270C, and 270D are all exposed to space 29V in the example illustrated in FIG. 25C. Such a configuration is preferable from the viewpoint of resistance to temperature cycling and suppression of solder flash. In this manner, at least one among soldered portions 270A, 270B, 270C, and 270D may be exposed to space 29V.

Next, the effects of the present exemplary embodiment are specifically described using Examples.

BGA type semiconductor packages having different pitches are used as a semiconductor package. There are three pitches of 0.65 mm, 0.5 mm, and 0.4 mm. In addition, a SnAgCu ball as a solder bump is mounted on the semiconductor package. In other words, these semiconductor packages are Daisy-chain wiring semiconductor packages.

### EXAMPLE

The following two kinds of solder pastes are used as a solder paste.

Solder paste D: Sn₄₂Bi₅₈ is used as solder and a bisphenol F type epoxy resin (“jER 806” manufactured by Mitsubishi Chemical Corporation) is used as a first binder. In addition, an imidazole-based curing agent (“2P4MZ” manufactured by Shikoku Kasei Co., Ltd.) is used as a curing agent, and a thixo agent (“TALEN VA-750B” manufactured by KYOEISHA CHEMICAL CO., LTD.) is used as a viscosity adjusting agent/thixotropic additive. Solder paste D is prepared by kneading these until a paste-like product is formed.

Solder paste E: solder paste E is prepared by kneading the same materials as those for solder paste D except that “ITOWAX J420” manufactured by ITOH OIL CHEMICALS CO., LTD. is used as a viscosity adjusting agent/thixotropic additive until a paste-like product is formed.

### Comparative Example

Solder paste F: solder paste F is prepared by kneading the same materials as those for solder paste D except that “THIXCIN R” manufactured by Elementis Japan is used as a viscosity adjusting agent/thixotropic additive until a paste-like product is formed.

### Evaluation Method

The above-mentioned BGA type semiconductor package is mounted on a wiring substrate using solder pastes D to F prepared as described above in the same manner as covering portion 140 and solder paste 260 illustrated in FIG. 5, and the drop resistance is evaluated. The influence of the kind of solder paste and the reflow temperature at the time of mounting on the impact resistance of the mounted product of BGA type semiconductor package is examined.

Specifically, the drop resistant life is evaluated as a drop resistance test. It is judged as defective if the resistance value rises by 20% or more in the semiconductor package when the semiconductor-mounted product is dropped from a height of 30 cm, and the number of drops until the occurrence of defect is evaluated as the drop resistant life.

The items and evaluation results of the respective samples are presented in (Table 3). Incidentally, in (Table 3), “pitch” indicates the pitch of BGA type semiconductor package and “presence or absence of linking” means whether or not a resin-reinforced portion is also formed on the mounting surface of the semiconductor package by linking two adjacent soldered portions to each other. “presence or absence of space” means whether or not a space in which the resin-reinforced portion is not formed is present between two adjacent soldered portions, and “height of resin-reinforced portion” means the height of the part most distant from the wiring of the resin-reinforced portion and is denoted as a percentage with respect to the height of the soldered portion from wiring 250. In addition, the drop resistant life is denoted as “200” in a case in which the number of drops before the occurrence of defect is 200 or more times, “150” in the case of from 150 times to 199 times, inclusive, and “100” in the case of from 100 times to 149 times, inclusive.

TABLE 3

| | | | | Presence | | | |
|---|---|---|---|---|---|---|---|
| | | | | or | Presence | | |
| | | Temperature | | absence | or | Height of resin- | Drop |
| | Solder | for reflow | Pitch | of | absence | reinforced | resistant |
| Sample | paste | (° C.) | (mm) | linking | of space | portion (%) | life (times) |
| E11 | D | 155-160 | 0.65 | Presence | Presence | 60 | ≥200 |
| E12 | D | 180 | 0.65 | Presence | Presence | 50 | ≥200 |
| E13 | D | 155-160 | 0.5 | Presence | Presence | 60 | ≥200 |
| E14 | D | 180 | 0.5 | Presence | Presence | 50 | ≥200 |
| E15 | D | 155-160 | 0.4 | Presence | Presence | 60 | ≥200 |
| E16 | D | 180 | 0.4 | Presence | Presence | 50 | ≥200 |
| E17 | E | 155-160 | 0.65 | Presence | Presence | 50 | ≥150 |
| E18 | E | 180 | 0.65 | Presence | Presence | 30 | ≥150 |
| E19 | E | 155-160 | 0.5 | Presence | Presence | 50 | ≥150 |
| E20 | E | 180 | 0.5 | Presence | Presence | 30 | ≥150 |
| E21 | E | 155-160 | 0.4 | Presence | Presence | 50 | ≥150 |
| E22 | E | 180 | 0.4 | Presence | Presence | 30 | ≥150 |
| C11 | F | 155-160 | 0.5 | Absence | Presence | 60 | ≥100 |
| C12 | F | 180 | 0.5 | Absence | Presence | 50 | ≥100 |
| C13 | F | 155-160 | 0.5 | Absence | Presence | 50 | ≥100 |
| C14 | F | 180 | 0.5 | Absence | Presence | 30 | 80 |

In a case in which solder paste D or solder paste E is used, the first binder is likely to flow and thus the resin-reinforced portions may be linked to each other at the lower part of two adjacent soldered portions. On the other hand, in a case in which solder paste C is used, the flowability of the first binder is low and thus the resin-reinforced portions are not linked to each other at the lower part of two adjacent soldered portions. However, in all samples, a space is present between the soldered portions.

In samples E11 to E22, the resin-reinforced portions at the lower part of two adjacent soldered portions are linked to each other. On the other hand, in samples C11 to C14, the resin-reinforced portions at the lower part of two adjacent soldered portions are not linked to each other. For this reason, in a case in which the heights of the resin-reinforced portions are the same as one another, samples E11 to E22 are superior in drop resistance to samples C11 to C14. This is because the rigidity can be enhanced as the resin-reinforced portions have a part at which the resin-reinforced portions are linked to each other at the lower part of adjacent soldered portions.

The first binder is more likely to flow by reflow at 180° C. than by reflow at 160° C., and thus the resin-reinforced portion is lower. However, in samples E18, E20, and E22, the drop resistance is not deteriorated even when the height of the soldered portion is 30% since a great number of parts at which the resins are linked to each other at the lower part of soldered portion are formed.

On the other hand, in sample C14, the first binder flows by reflow at 180° C., and the height of the soldered portion decreases to 30%. However, the drop resistance is deteriorated as compared to that in the case of reflow at 160° C. since the resin-reinforced portions do not have parts at which the resin-reinforced portions are linked to each other at the lower part of adjacent soldered portions.

### Sixth Exemplary Embodiment

In the present exemplary embodiment, a structure by which both the repairability and the drop resistant strength are achieved is described. First, the repairability is briefly described.

Troubles may be caused to the semiconductor package or the wiring substrate in the inspection after the semiconductor-mounted product is assembled, or troubles may be caused to the semiconductor package or the wiring substrate during actual use. In such a case, the semiconductor package and the wiring substrate may be separated from each other and the semiconductor package or wiring substrate without any abnormality may be combined with a new part (semiconductor package or wiring substrate).

When the semiconductor package and wiring substrate which have been assembled once are separated from each other in this manner, the semiconductor-mounted product is heated and the soldered portion is divided at the interface between the first solder region and the second solder region. Alternatively, in a case in which the melting point of the second solder region is lower than the melting point of the first solder region, the soldered portion is divided in the second solder region.

In general, a semiconductor package has a large number of bumps such as BGA, and wirings are formed on a wiring substrate by the number corresponding to the number of bumps. Hence, the semiconductor-mounted product has a large number of soldered portions, and each of the soldered portions is covered with the resin-reinforced portion as described in the first to fifth exemplary embodiments. When the resin-reinforced portion covers the resin-reinforced portions without a gap at the time of separation of the semiconductor package from the wiring substrate, the resin-reinforced portion interferes with the separation of the semiconductor package from the wiring substrate. In the following description, the ease of separation of the semiconductor package from the wiring substrate is referred to as repairability.

As described above, when the semiconductor package and the wiring substrate are separated from each other, the soldered portion is divided at the interface between the first solder region and the second solder region or in the second solder region. Hence, the repairability is improved if there are a great number of voids in the resin-reinforced portion at the height position in the vicinity of the place to be divided. Next, the height position at which the number of voids (void ratio) in the resin-reinforced portion is evaluated is described.

For example, as illustrated on the right side of FIG. 8, in a case in which the height of resin-reinforced portion 290 is the same as the height of soldered portion 270, the reinforcing strength by resin-reinforced portion 290 is high, and thus it is easy to apply in a case in which second solder region 350 is high and the position of the boundary between first solder region 340 and second solder region 350 is high. On the other and, as illustrated on the left side of FIG. 8, in a case in which the height of resin-reinforced portion 290 is lower than the height of soldered portion 270, the reinforcing strength by resin-reinforced portion 290 is relatively low, and thus it is easy to apply in a case in which second solder region 350 is low and the position of the boundary between first solder region 340 and second solder region 350 is low.

As described in the first exemplary embodiment, it is preferable that height 300 of resin-reinforced portion 290 in FIG. 4A and FIG. 8 is set to be 40% or more of height 280 of soldered portion 270. In addition, as illustrated in FIG. 24A in the fifth exemplary embodiment, in a case in which resin-reinforced portion 290 links two adjacent soldered portions 270 to each other, it is preferable that the height of the part most distant from wiring 250 of resin-reinforced portion 290 is 30% or more of the height of soldered portion 270 from wiring 250.

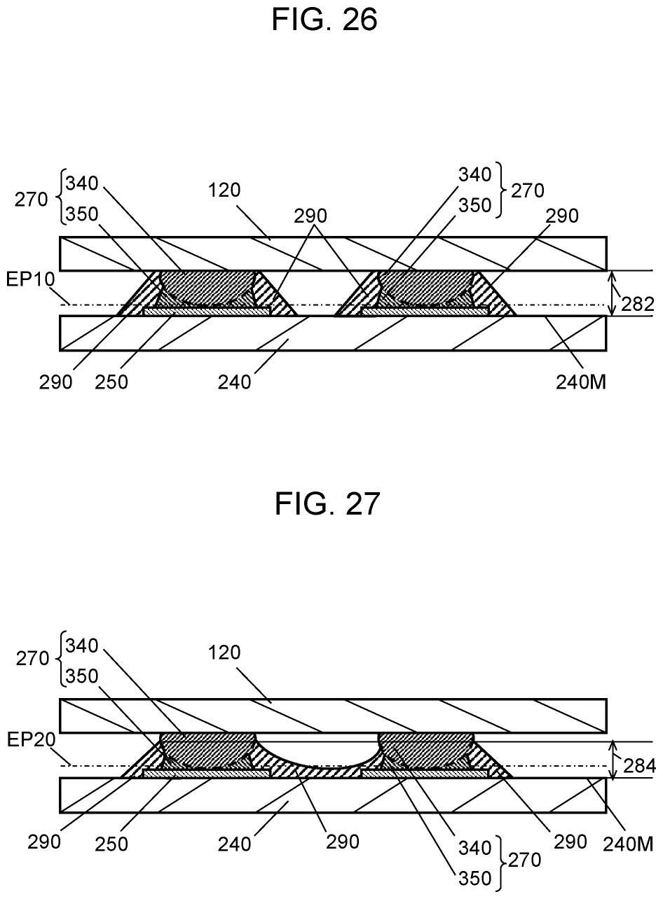

The height position at which the void ratio is evaluated and which is determined in consideration of these conditions is described with reference to FIG. 26 and FIG. 27. FIG. 26 and FIG. 27 are schematic cross-sectional views illustrating the height position at which the void ratio is evaluated.

As illustrated in FIG. 26, it is considered to be proper that the void ratio is evaluated on surface (virtual surface) EP10 which is apart from mounting surface 240M of wiring substrate 240 by ¼ of distance 282 between semiconductor package 120 and wiring substrate 240 and is parallel to mounting surface 240M.

Incidentally, in a case in which the height of resin-reinforced portion 290 is lower than the height of soldered portion 270 as illustrated on the left side of FIG. 8 and in FIG. 27, the height position at which the void ratio is evaluated may be determined based on the height of resin-reinforced portion 290. In other words, the void ratio can be evaluated on surface (virtual surface) EP20 which is apart from mounting surface 240M by ⅓ of distance 284 from the position most distant from wiring 250 of resin-reinforced portion 290 to mounting surface 240M and is parallel to mounting surface 240M.

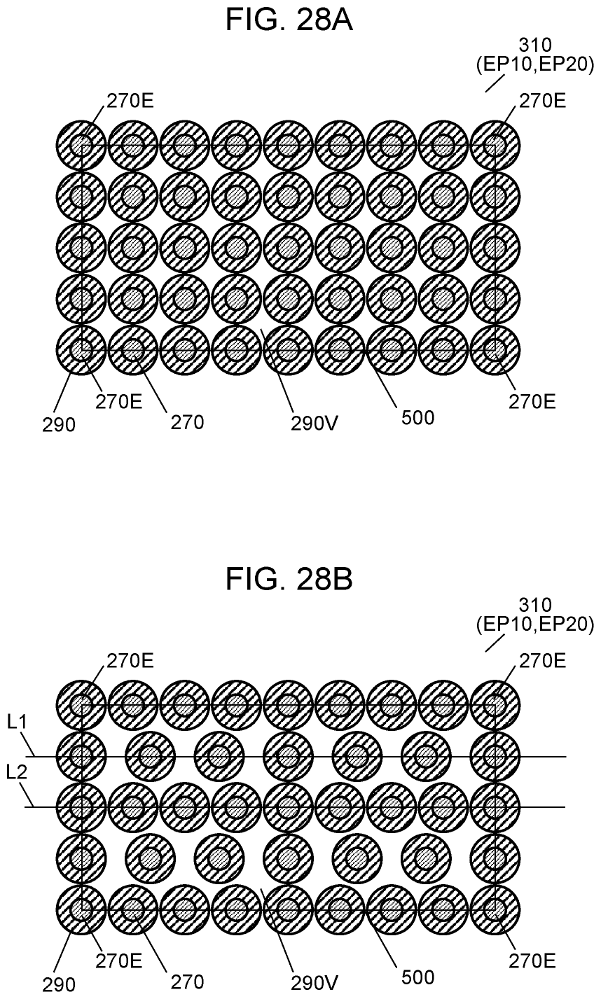

Next, an example of the definition of void ratio on surface EP10 (EP20) for evaluating the void ratio is briefly described with reference to FIG. 28A. FIG. 28A is a schematic cross-sectional view of semiconductor-mounted product 310 for explaining the void ratio. As described above, semiconductor package 310 has a large number of soldered portions 270. Hence, the proportion of void 290V present in polygon 500 connecting the centers of soldered portions 270E located at the outermost positions among soldered portions 270 to the sum of void 290V and resin-reinforced portion 290 present in polygon 500 can be evaluated as the void ratio.

The preferred range of void ratio is from 10% to 99%, inclusive, from the viewpoint of repairability. This range is described with reference to the following Examples. Incidentally, the drop resistance can be achieved as long as resin-reinforced portion 290 appropriately covers soldered portion 270 regardless of the void ratio.

### EXAMPLE

A semiconductor package having BGAs lined up so that 400 pins form a square with a 0.5 mm pitch is used. On the wiring substrate, 400 wirings corresponding to these BGAs are formed. A soldered portion and a resin-reinforced portion are formed using these semiconductor packages and wiring substrates by the method described in any of the first to fifth exemplary embodiments. At this time, the void ratio is changed as presented in Table 4 by adjusting the amount of the binder forming the resin-reinforced portion. A resin composition containing an epoxy resin as a main component is used as the binder, Sn-3Ag-0.5Cu is used as the first solder for forming the first solder region, and 42Sn-58Bi is used as the first solder for forming the second solder region. The void ratio is from 10% to 99%, inclusive, in sample E61 to sample E66, and the void ratio is less than 10% in sample C61 to sample C63.

Next, the evaluation method and evaluation criteria of the repairability are described. The semiconductor-mounted product formed as described above is heated by setting the peak temperature to 150° C. and held at the peak temperature for 30 seconds using an infrared rework apparatus (IR/PL 550) manufactured by Kurtz Ersa Corporation. Immediately thereafter, the BGA is manually removed using tweezers. It is evaluated to be GD (Good) if the semiconductor package can be peeled off from the wiring substrate with light force (for example, less than 3 N), it is evaluated to be OK if the semiconductor package can be peeled off from the wiring substrate with relatively strong force (for example, 3N or more and less than 5N), and it is evaluated to be NG if the semiconductor package can be peeled off from the wiring substrate with strong force (for example, 5N or more). The void ratio and the evaluation results are presented together in (Table 4).

TABLE 4

| Sample | Void ratio (%) | Repairability |
|---|---|---|
| E61 | 99 | GD |
| E62 | 90 | GD |
| E63 | 80 | GD |
| E64 | 50 | GD |
| E65 | 30 | OK |
| E66 | 10 | OK |
| C61 | 9 | NG |
| C62 | 5 | NG |
| C63 | 3 | NG |

As apparent from the evaluation results, the semiconductor package can be peeled off from the wiring substrate with light force in a case in which the void ratio is from 50% to 99%, inclusive, (sample E61 to sample E64). In addition, the semiconductor package can be peeled off from the wiring substrate with relatively strong force in a case in which the void ratio is from 10% to 30%, inclusive, (sample E65 and sample E66). On the other hand, in a case in which the void ratio is less than 10% (sample C61 to sample C63), the repairability is low since the semiconductor package cannot be peeled off from the wiring substrate unless strong force is applied.

On the other hand, when the void ratio exceeds 99%, space 29V described in the fifth exemplary embodiment is extremely small and the effect of relieving the stress generated when the semiconductor-mounted product is exposed to an environment in which the temperature periodically changes is substantially nonfunctional.

Incidentally, in Example above, the case in which the centers of four soldered portions 270E located at the outermost positions among soldered portions 270 are located at the apexes of a square has been described, but the centers of four soldered portions 270E located at the outermost positions among soldered portions 270 may be located at the apexes of rectangle 270E as illustrated in FIG. 28A. In addition, the case in which soldered portion 270 has a constant pitch has been described, but the present invention is not limited to this. As illustrated in FIG. 28B, soldered portions 270 may be arranged along either of parallel first straight line L1 or parallel second straight line L2 and the pitch of soldered portions 270 arranged along first straight line L1 may be different from the pitch of soldered portions 270 arranged along second straight line L2. Among the plurality of soldered portions 270, the centers of soldered portions 270E located at the outermost positions may form polygon 500 having a shape other than a square or a rectangle. The same effects as those in sample E61 to sample E66 are obtained if the proportion of void 290V present in polygon 500 to the sum of void 290V and resin-reinforced portion 290 present in polygon 500 is from 10% to 99%, inclusive.

According to the semiconductor part and semiconductor-mounted product of the present invention, it is possible to improve the repairability of the semiconductor-mounted product as well as the reliability of various kinds of electronic devices.

1. A semiconductor device comprising:
a semiconductor package;
a wiring substrate having a mounting surface on which a wiring is disposed and the semiconductor package is to be mounted;
four or more soldered portions electrically connecting the semiconductor package to the wiring; and
a resin-reinforced portion disposed on a side surface of each of the four or more soldered portions, a height of the resin-reinforced portion is the same as a height of the soldered portion,
wherein
each of the four or more soldered portions has a first solder region located closer to the semiconductor package than the wiring substrate and a second solder region located closer to the wiring substrate than the semiconductor package, and
a proportion of (i) a void present in a polygon connecting centers of soldered portions located at outermost positions among the four or more soldered portions to (ii) a sum of the void and the resin-reinforced portion is from 10% to 99%, inclusive, in a surface that is apart from the mounting surface by ¼ of a distance between the semiconductor package and the wiring substrate and is parallel to the mounting surface, and
the resin-reinforced portion located on the wiring substrate by linking with two soldered portions that are disposed adjacent to each other.

2. The semiconductor device according to claim 1, wherein the centers of four soldered portions located at outermost positions among the four or more soldered portions are located at apexes of a square or a rectangle.

3. The semiconductor device according to claim 1, wherein:
the four or more soldered portions are arranged along either of a parallel first straight line or a parallel second straight line; and
a pitch of soldered portions arranged along the parallel first straight line is different from a pitch of soldered portions arranged along the parallel second straight line.

4. The semiconductor device according to claim 1, wherein a melting point of the second solder region is lower than a melting point of the first solder region.

5. The semiconductor device according to claim 1, wherein:
the first solder region mainly contains Sn-Ag-Cu-based first solder; and
the second solder region mainly contains Sn-Bi-based or Sn-Bi-Ag-Cu-based second solder.

6. The semiconductor device according to claim 1, wherein a height of a part furthest from the wiring of the resin-reinforced portion is from 30% to 100%, inclusive, of a height of one of the soldered portions from the wiring.

7. The semiconductor device according to claim 1, wherein the second solder region contains Bi and the resin-reinforced portion covers at least a side surface of the second solder region.

8. The semiconductor device according to claim 1, wherein a part of the resin-reinforced portion covers a side surface of the second solder region and also extends from the side surface of the second solder region to a side surface of the first solder region to cover the side surface of the first solder region.

9. The semiconductor device according to claim 1, wherein a part of the resin-reinforced portion continuously covers from a top of the wiring substrate to a mounting surface of the semiconductor package via a side surface of one of the soldered portions.

10. The semiconductor device according to claim 1, further comprising an insulating filling material for linking the semiconductor package to the wiring substrate at a peripheral portion of the semiconductor package.
